(19) United States
(12) Patent Application Publication
(10) Pub. No.: US 2015/0154885 A1
(43) Pub. Date: Jun. 4, 2015

(54) DEVICES, METHODS, AND SYSTEMS FOR HIGH-RESOLUTION TACTILE DISPLAYS

(71) Applicant: Northeastern University, Boston, MA (US)

(72) Inventors: Carol LIVERMORE-CLIFFORD, Framingham, MA (US); Xin XIE, Malden, MA (US); Seth TELLER, Cambridge, MA (US); Luis VELASQUEZ-GARCIA, Newton, MA (US)

(21) Appl. No.: 14/589,732

(22) Filed: Jan. 5, 2015

Related U.S. Application Data
(63) Continuation of application No. PCT/US2013/049328, filed on Jul. 3, 2013.
(60) Provisional application No. 61/668,318, filed on Jul. 5, 2012.

(51) Int. Cl. G09B 21/00; H01L 41/29; H01L 41/338

(52) U.S. Cl. CPC G09B 21/003; H01L 41/338; H01L 41/29

(57) ABSTRACT

The present disclosure introduces new multi-functional vibrating devices, methods of using the devices, and methods of manufacturing the devices. A multi-functional vibrating device can include one or more actuators, each paired with an amplifier capable of converting small lateral vibration into large vertical vibration. The present disclosure also involves interactive information acquisition technologies and assistive technologies, particularly devices, methods, and systems for tactile information transfer and acquisition. Some embodiments incorporate multi-functional vibrational devices, methods, and systems to achieve unique structural and operational characteristics—such as high-resolution, robustness, versatility, compactness, and/or rapid refresh rates—for communicating information. Some embodiments can convert information from a format that is less convenient and/or accessible in some cases (e.g., visual or audio) to an intuitive and/or private format (e.g., tactile patterns and motions).

### CROSS-REFERENCE TO RELATED APPLICATIONS

This application is a continuation of International Application No. PCT/US2013/049328, filed on Jul. 3, 2013, and published on Jan. 9, 2014 as WO 2014/008401, which claims the benefit of U.S. Provisional Patent No. 61/668,318, filed Jul. 5, 2012, the entire contents of each of which are hereby incorporated by reference herein.

### TECHNICAL FIELD

The present disclosure relates generally to interactive information acquisition technologies and assistive technologies. Particularly, the present disclosure relates to a robust multifunctional actuator-amplifier device capable of converting small lateral vibration into large vertical vibration. More specifically, the present disclosure relates to devices, methods, and systems for high-resolution tactile displays.

### BACKGROUND

A visual impairment is a significant functional limitation of the eye(s) and/or visual processing system resulting from disease, trauma, or congenital or degenerative disorders that cannot be corrected to a normal level by conventional treatments (i.e., contact lenses or glasses). Visual impairments range along a spectrum from partial sight and low vision to total absence of sight. The severity of a visual impairment is indicated by evaluating, for example, the visual field and the spatial resolution (i.e., visual acuity) of the visual processing system. Visual acuity can be tested by having a person identify standardized test symbols of progressively smaller size on an eye chart. In the expression “20/40 vision,” “20” is the distance in feet between the patient and the chart and “40” means the patient can read the chart as well as a person with normal vision could read the same chart from 40 feet away. Vision of 20/20 is considered nominal performance, while 20/40 vision is considered half as good as nominal performance.

As of 2012, the World Health Organization (WHO) estimates that approximately 285 million people have visual impairments—about 39 million are blind and about 246 million have low vision—worldwide. In the United States alone, the 1994-1995 National Health Interview Survey on Disability reported 1.3 million people with “legal blindness” (i.e., visual acuity equal to or less than 20/200 with the best possible correction, and/or a visual field equal to or less than 20 degrees without moving or turning the head). Although some vision problems are correctable, WHO research indicates that 20% of visual impairments cannot be prevented or cured.

Visual impairments can make it difficult to accomplish many everyday tasks, including navigating, visualizing images or graphic information, and identifying nearby people, places, and things. Consider unstructured and/or unfamiliar environments, such as a conference center. Conventional navigational tools (e.g., canes or assistance animals) can help a visually impaired person avoid obstacles, but these tools are not well-suited for helping the person, for example, locate a reception table, distinguish between meeting rooms, or return to his or her seat at a meeting. Or, consider situations in which graphical information is presented, such as in classroom instruction or standardized testing. Proactive educators may help a visually impaired person by providing accessible materials (with, e.g., large print, braille, and tactile graphics) and/or verbalizing what is shown (in, e.g., images, maps, videos, models, and demonstrations); however, some graphical information is incapable of being rendered in a fixed and accessible format (e.g., complicated images with multiple lines, patterns, and/or colors) and not all educators are positioned to provide special attention to a visually impaired person.

Depending on the severity of and when the visual impairment first occurs, assistive technologies may help people with visual impairments in a variety of personal, professional, and educational settings. Many existing assistive technologies convey information to people with visual impairments by using electronic interfaces to convert information to audible speech (e.g., optophones and some screen readers). However, an auditory approach either precludes privacy (i.e., due to use of a speaker) or requires the dedication of at least one ear to using headphones, earbuds, canalphones, etc. Other assistive technologies provide magnified views of text and/or images, but the usefulness of magnification is limited by the severity of an individual's visual impairment capabilities and mostly used to help those with partial sight or low vision. Thus, assistive technologies with tactile components may be more appropriate for conveying information according to the personal, professional, and educational needs of a person with a visual impairment.

The braille writing system is the most well-known example of tactile information acquisition. Developed in the early 19th century, braille characters are small rectangular cells that contain tiny palpable bumps or raised dots. The number and arrangement of the dots distinguish one character from another. Braille can be transcribed with a slate and stylus, typed on a braille writer or a computer that prints with a braille embosser, or produced on an electromechanical device called a refreshable braille reader that displays a sequence of braille characters, using combinations of six (or in some cases, eight) round-tipped piezoelectric pins raised through holes in a flat surface. Braille is an excellent system for providing information to a visually-impaired person, but only so long as the person is braille-literate (i.e., braille reading has a steep learning curve), the information is textual (vs. graphic), and the information is available in braille, an electronic format that can be translated to braille, or in a physical format of a quality sufficient for scanning and applying optical character recognition.

Electroactive polymers (EAPs) are being developed to replace piezoelectric pins in refreshable braille readers. Rows of electrodes on one side of an EAP film and columns of electrodes on the other side control an array of braille dots mounted on the film. By selectively stimulating the EAP film with voltage to cause one or more local thickness reductions, the unnecessary dot(s) are lowered and the remaining dots represent braille characters. Typically, the responsive areas of an EAP film are larger (e.g., several mm²) with greater amplitudes than braille and longer characteristic time scales than piezoelectric pins.

In the 1960s, an electromechanical device called the Optacon (OPtical to TActile CONverter) was developed to enable visually-impaired people to read printed text without first translating the information into braille. Users manually scanned a page with the Optacon, which transferred the image of each character into a 6×24 array of vibrating piezoelectric pins, the tips of which replicated each character on the page. No longer in production, the Optacon had its own additional limitations, including the relatively slow speed of reproducing character-by-character (compared to scanning and performing optical character recognition of an entire document), applicability to only printed text, and a steep learning curve due to, for example, the complexity of the device and the unfamiliarity of some users with the characters.

As for tactile acquisition of non-textual information, static two-dimensional tactile images can be reproduced by, for example, thermoforming, embossing, or using swell paper (also known as microcapsule or hot spot paper). Static three-dimensional tactile models can be produced by, for example, machining or additive manufacturing (e.g., 3D printing). These technologies for tactile information acquisition are useful but do not fill the need for a responsive, real-time information acquisition system.

Hybrid tactile interface technologies integrate finger-driven touch interfaces with audio, graphical, and/or tactile feedback. For example, a tactile map may be configured to play an audio or video recording describing an object, symbol, or area as it is engaged by a user's finger (e.g., the sound of running water can be used to describe rivers or other bodies of water). Disney's TeslaTouch technology uses electrovibration to generate periodic electrostatic friction between a user's finger and a glass touch screen. When combined with an interactive graphical display, TeslaTouch enables the design of interfaces that allow a user to feel virtual elements and their properties (e.g., textures).

At present, these assistive technologies do not adequately address the personal, professional, and educational needs of a person with a visual impairment. A broad range of different users, but especially the visually impaired, would benefit from tactile display technologies that are intuitive, versatile, private, compact, high-resolution, robust, and/or rapidly-refreshable.

### BRIEF SUMMARY

The present application discloses tactile display devices, methods, and systems with unique structural and operational characteristics for acquiring information in intuitive spatiotemporal and vibrational frequency-based formats. For users with visual impairments, the disclosed embodiments are intended to enhance their independence, educational participation, and professional engagement.

In one embodiment, a high-resolution actuating array includes an array of two or more actuators in a plane, each having a long dimension in a first direction in the plane, one or more electrodes positioned in contact with one or more surfaces of each actuator, the two or more actuators in the array being independently configured and arranged to contract and/or expand in the first direction upon application of one or more electric voltages to the one or more electrodes, and an amplifier with one or more bendable elements and one or more rigid arms positioned in contact with each actuator, wherein at least one rigid arm is flexibly attached to a surface of the actuator, the at least one rigid arm being configured and arranged to rotate away from the surface of the actuator when the actuator contracts in the first direction and to rotate toward the surface of the actuator when the actuator expands in the first direction.

In an embodiment, the two or more actuators in the array are configured to have operating frequencies of approximately 10 Hz to 400 Hz. In an embodiment, the two or more actuators in the array are configured and arranged to be independently actuated with a unique memory element in an underlying memory circuit, a unique voltage signal, and/or a unique current flow path. In an embodiment, a high-resolution actuating array further includes a printed circuit board baseplate and/or a silicon chip configured and arranged for mounting the array of actuators. In an embodiment, at least one of the one or more bendable elements is a pin hinge, a magnetic hinge, and/or a living hinge.

In an embodiment, each amplifier includes a pair of rigid arms, each having a first end connected with a first bendable element to an opposite end of the actuator along its long dimension and a second bendable element connected to each second end of the pair of rigid arms, wherein the pair of rigid arms are configured and arranged to rotate away from the surface of the actuator to form an inverted V-shape when the actuator contracts in the first direction and rotate toward the surface of the actuator when the actuator expands in the first direction.

In an embodiment, each amplifier includes one or more rigid arms, each having a first end connected with a first bendable element to an end of the actuator along its long dimension and a rigid wall protruding from the surface of the actuator, wherein a second end of each of the one or more rigid arms is in contact with a surface of the wall, wherein each second end of the one or more rigid arms is configured and arranged to move away from the surface of the actuator in a second direction, the second direction being approximately perpendicular to the plane, when the actuator contracts in the first direction and to move toward the surface of the actuator in the second direction when the actuator expands in the first direction.

In an embodiment, each amplifier includes a first pair of rigid arms, each having a first end connected with a first bendable element to an opposite end of the actuator along its long dimension and a second bendable element connected to each center of the first pair of rigid arms, wherein the first pair of rigid arms is configured and arranged to rotate away from the surface of the actuator to form an X-shape when the actuator contracts in the first direction and to rotate toward the surface of the actuator in the second direction when the actuator expands in the first direction.

In an embodiment, each amplifier further includes a second pair of rigid arms, each having a first end connected with a third bendable element to a second end of an opposite arm of the first pair of rigid arms and a final bendable element connected to each second end of the second pair of rigid arms, wherein the second pair of rigid arms is configured and arranged to rotate away from the surface of the actuator to form an inverted V-shape when the actuator contracts in the first direction and to rotate toward the surface of the actuator when the actuator expands in the first direction.

In an embodiment, each amplifier further includes N pairs of rigid arms, wherein N is a whole number, and N bendable elements, each connected to each center of a pair of rigid arms, wherein the N pairs of rigid arms are stacked such that each arm has a first end connected with another bendable element to an opposite second end of an arm of a previous pair of rigid arms in the stack, wherein the N pairs of rigid arms are configured and arranged to rotate away from the surface of the actuator to form N X-shapes when the actuator contracts in the first direction and to rotate toward the surface of the actuator when the actuator expands in the first direction.

In an embodiment, each amplifier further includes a final pair of rigid arms, each having a first end connected with another bendable element to a second end of an opposite arm of the Nth pair of rigid arms and a final bendable element connected to each second end of the final pair of rigid arms, wherein the final pair of rigid arms is configured and arranged to rotate away from the surface of the actuator to form an inverted V-shape when the actuator contracts in the first direction and to rotate toward the surface of the actuator when the actuator expands in the first direction.

In an embodiment, a high-resolution actuating array further includes a pin protruding from each amplifier in a second direction, the second direction being approximately perpendicular to the plane. In an embodiment, a high-resolution actuating array further includes a pin protruding from each amplifier in the first direction. In an embodiment, a high-resolution actuating array further includes at least one of a cover and cap plate defining an array of two or more access holes configured to align with an array of two or more pins.

In an embodiment, the array of two or more actuators has a rectilinear layout. In an embodiment, the array of two or more actuators has an offset layout.

In an embodiment, the array of two or more actuators in the plane is stacked with a second array in a parallel plane, the second array including two or more actuators, each having a long dimension in the first direction, one or more electrodes positioned in contact with one or more surfaces of each actuator, the two or more actuators in the second array being independently configured and arranged to at least one of contract and expand in the first direction upon application of one or more electric voltages to the one or more electrodes, and an amplifier with one or more bendable elements and one or more rigid arms positioned in contact with each actuator, wherein at least one rigid arm is flexibly attached to a surface of the actuator, the at least one rigid arm being configured and arranged to rotate away from the surface of the actuator when the actuator contracts in the first direction and to rotate toward the surface of the actuator when the actuator expands in the first direction. In an embodiment, a high-resolution actuating array further includes N arrays of two or more actuators stacked in N parallel planes, wherein N is a whole number.

In one embodiment, a method of using a high-resolution actuating array includes obtaining an array of two or more actuators in a plane, each having a long dimension in a first direction in the plane, wherein an amplifier with one or more bendable elements and one or more rigid arms is positioned in contact with each actuator and wherein at least one rigid arm is flexibly attached to a surface of the actuator, and applying one or more electric voltages to one or more electrodes positioned in contact with one or more surfaces of at least one actuator such that the at least one actuator contracts and/or expands in the first direction and the at least one rigid arm rotates away from the surface of the actuator when the actuator contracts in the first direction and rotates toward the surface of the actuator when the actuator expands in the first direction.

In one embodiment, a method of manufacturing a high-resolution actuating array includes cutting an array of two or more actuators in a plane from a piezoelectric sheet, each actuator having a long dimension in a first direction in the plane, defining one or more electrodes positioned in contact with one or more surfaces of each actuator, the two or more actuators in the array being independently configured and arranged to contract and/or expand in the first direction upon application of one or more electric voltages to the one or more electrodes, and fabricating an amplifier with one or more bendable elements and one or more rigid arms is positioned in contact with each actuator, wherein at least one rigid arm is flexibly attached to a surface of the actuator, the at least one rigid arm being configured and arranged to rotate away from the surface of the actuator when the actuator contracts in the first direction and to rotate toward the surface of the actuator when the actuator expands in the first direction.

In an embodiment, the array of two or more actuators is cut using at least one of laser cutting, ultrasonic machining, and waterjet cutting. In an embodiment, gaps are cut into the piezoelectric sheet to maintain at least one of a frame around the array and one or more tethers between the two or more actuators. In an embodiment, the array of two or more actuators is patterned with a rectilinear layout. In an embodiment, the array of two or more actuators is patterned with an offset layout. In an embodiment, the one or more electrodes are defined on the one or more surfaces of at least one actuator by at least one of laser machining, ultrasonic machining, and waterjet cutting, photolithography, and other forms of etching. In an embodiment, the amplifier is fabricated using at least one of 3D printing, screen printing, injection molding, and stamping from a metal sheet. In an embodiment, the amplifier is formed as a monolithic array connected together by at least one of a set of snap-off tabs and tabs that can be removed by machining.

In one embodiment, a high-resolution tactile display system includes a high-resolution actuating array according to some embodiments, a processor configured to encode information as one or more tactons and signal the application of one or more electric voltages to the one or more electrodes of at least one actuator, and storage for storing data and executable instructions to be used by the processor.

In an embodiment, the one or more tactons include at least one of a spatial pattern of actuation, a spatiotemporal pattern of actuation, a series of actuations sensed as motion, a series of rhythmic actuations, a variation in amplitude, and a variation in operating frequency. In an embodiment, a high-resolution tactile display system further includes a tactile user interface. In an embodiment, a high-resolution tactile display system further includes a microphone, a speaker, a navigation device, a sensor, and/or a network connection.

In one embodiment, a method of using a high-resolution tactile display system includes obtaining information for display, encoding the information as one or more tactons, and signaling the application of one or more electric voltages to one or more electrodes of at least one actuator in a high-resolution actuating array according to some embodiments.

In an embodiment, the one or more tactons include at least one of a spatial pattern of actuation, a spatiotemporal pattern of actuation, a series of actuations sensed as motion, a series of rhythmic actuations, a variation in amplitude, and a variation in operating frequency.

Other systems, processes, and features will become apparent to one with skill in the art upon examination of the following drawings and detailed description. It is intended that all such additional systems, processes, and features be included within this description, be within the scope of the present invention, and be protected by the accompanying claims.

### BRIEF DESCRIPTION OF THE FIGURES

The following figures are presented for the purpose of illustration only, and are not intended to be limiting:

FIG. 1 is a schematic side view of a multi-functional vibrating device with a two-arm, scissor-like amplifier mechanism in accordance with some embodiments;

FIG. 2 is a schematic side view of a multi-functional vibrating device with a two-arm, scissor-like amplifier mechanism and a protrusion in accordance with some embodiments;

FIG. 3 is a schematic side view of a multi-functional vibrating device with a single-member, scissor-like amplifier mechanism with living hinges in accordance with some embodiments;

FIG. 4 is a schematic side view of a multi-functional vibrating device with a single-member, scissor-like amplifier mechanism with living hinges and a protrusion in accordance with some embodiments;

FIG. 5 is a schematic side view of a multi-functional vibrating device with a single-member, scissor-like amplifier mechanism with living hinges and an offset protrusion in accordance with some embodiments;

FIG. 6 is a schematic side view of a multi-functional vibrating device with an alternative single-member, scissor-like amplifier mechanism with living hinges in accordance with some embodiments;

FIG. 7 is a schematic side view of a multi-functional vibrating device with an alternative single-member, scissor-like amplifier mechanism with living hinges and a protrusion in accordance with some embodiments;

FIG. 8 is a schematic side view of a multi-functional vibrating device with an alternative single-member, scissor-like amplifier mechanism with living hinges and an offset protrusion in accordance with some embodiments;

FIG. 9 is a schematic side view of a multi-functional vibrating device with a one-arm, scissor-like amplifier mechanism with a living hinge, a vertical wall, and an offset protrusion in accordance with some embodiments;

FIG. 10 is a schematic side view of a multi-functional vibrating device with a two-arm, scissor-like amplifier mechanism with living hinges, a vertical wall, and an offset protrusion in accordance with some embodiments;

FIG. 11 is a schematic side view of a multi-functional vibrating device with a four-arm, stacked scissor-like amplifier mechanism in accordance with some embodiments;

FIG. 12 is a schematic side view of a multi-functional vibrating device with a four-arm, stacked scissor-like amplifier mechanism and a protrusion in accordance with some embodiments;

FIG. 13 is a schematic side view of a multi-functional vibrating device with a vertically-oriented actuator and a single-member, scissor-like amplifier mechanism with living hinges and a protrusion in accordance with some embodiments;

FIG. 14A is a schematic side view of a multi-functional vibrating device with a base and cover in accordance with some embodiments, and FIG. 14B is a schematic side view of two series of devices like that in FIG. 14A in accordance with some embodiments;

FIGS. 15A-15D illustrate a two dimensional array of multi-functional vibrating devices and selective actuation in accordance with some embodiments;

FIGS. 16A-16C are schematic top views of different layouts for an array of vibrating devices in accordance with some embodiments;

FIG. 17 is a schematic side view of a two-layer array of vibrating devices in accordance with some embodiments;

FIG. 18A is a diagram of the actuator and amplifier geometry of a tactel in accordance with some embodiments, and FIG. 18B is a diagram of horizontal and vertical loads from a user in accordance with some embodiments;

FIG. 19 is a plot illustrating bending stiffness and deflection constraints on a bending beam actuator as a function of thickness in accordance with some embodiments;

FIG. 20 is a plot illustrating bending stiffness and deflection constraints on a tactel in accordance with some embodiments;

FIG. 21A is a plot of the deflection as a function of the angle θ for an actuator in accordance with some embodiments, and FIG. 21B is a plot of the maximum total stress as a function of the angle θ for an actuator in accordance with some embodiments;

FIG. 22 is a schematic top view of an actuator sheet manufactured to form a patterned array of actuators in accordance with some embodiments;

FIG. 23A is a schematic bottom view of an actuator plate with separate tactel connections in accordance with some embodiments, FIG. 23B is a schematic side view of a PZT plate assembled onto PCB substrate, and FIG. 23C illustrates an amplifier geometry that provides the necessary amplifier functionality according to some embodiments; and

FIG. 24 is a diagram for an interactive tactile display system in accordance with some embodiments.

### DETAILED DESCRIPTION

Unless otherwise defined, all technical and scientific terms used herein have the same meaning as commonly understood by one of ordinary skill in the art to which this invention belongs. Although methods and materials similar or equivalent to those described herein can be used in the practice or testing of the present invention, suitable methods and materials are described below. All publications, patent applications, patents, and other references mentioned herein are incorporated by reference in their entirety. In case of conflict, the present specification, including definitions, will control. In addition, the materials, methods, and examples are illustrative only and not intended to be limiting.

The present disclosure introduces new multifunctional actuator-amplifier devices, methods of using the devices, and methods of manufacturing the devices. In some embodiments, a multifunctional actuator-amplifier device includes an actuator paired with an amplifier. In some embodiments, a multifunctional actuator-amplifier device is capable of converting small lateral vibration into large vertical vibration. In further embodiments, a multifunctional actuator-amplifier device includes more than one actuator-amplifier pair. In some embodiments, a plurality of actuator-amplifier pairs is arranged in an array.

The present disclosure also involves interactive information acquisition technologies and assistive technologies, particularly devices, methods, and systems for tactile information acquisition. Some embodiments incorporate multifunctional actuator-amplifier devices, methods and systems to achieve unique structural and operational characteristics—such as high-resolution, robustness, versatility, compactness, and/or rapid refresh rates—for acquiring information. Some embodiments can convert information from a format that is less convenient and/or accessible in some cases (e.g., visual or audio) to an intuitive and/or private format (e.g., tactile patterns and motions). In some embodiments, information can be acquired and/or conveyed using appropriate sensors to characterize changing environments, perception algorithms, and/or hierarchies of information priorities. A user can use some embodiments to interact seamlessly with conventional computer systems and applications and/or specialized (e.g., navigational and social awareness) systems and applications.

Devices, methods, and systems to acquire and/or convey information through the sense of touch are particularly useful for individuals with low or impaired vision. Some embodiments can empower, for example, a visually-impaired person to respond to situational, navigational, and/or graphical cues that sighted individuals take for granted. Further embodiments can enable and/or enhance the integration of the visually impaired into a variety of personal, professional, and educational settings. For example, use of some embodiments may qualify low-vision students to sit for the same standardized tests and in the same environments as their normal-vision peers. The public benefits of such embodiments can include not only improvements in user quality of life but also an increase in user self-sufficiency, engagement, and productivity in society.

### Characteristics of Touch Receptors

To achieve unique structural and operational characteristics—such as high-resolution, robustness, versatility, compactness, and/or rapid refresh rates—for tactile information acquisition, some embodiments are designed to interact with user touch receptors. Human skin contains a variety of different mechanoreceptors (i.e., touch receptors), each with its own structure, placement, frequency response, spatial resolution, adaptation speed, and necessary magnitude of skin indentation to produce a response. The presence and spacing of mechanoreceptors can also vary between glabrous (naturally hairless) and hairy skin.

Receptors terminating in Merkel cells are found near the surface of the skin and have excellent spatial resolution, with an ability to resolve stimuli separated by as little as about 0.5 mm in glabrous skin. Merkel receptors are the primary receptors that are used in reading braille. However, their best sensitivity to skin indentation is found in the range of approximately 5 Hz to 15 Hz, at which frequency a minimum skin indentation on the order of about 50 μm is typically required to produce a response. Braille dots are safely above this level, at about 500 μm.

Meissner's corpuscles have maximum sensitivity between about 20 Hz to 50 Hz and have a minimum sensitivity to skin indentation of about 14 μm. Meissner's corpuscles are located with a high density of about 150 receptors/cm², but they have a relatively lower spatial resolution and respond rather uniformly across their entire receptive field, which is approximately 3 mm to 5 mm.

The highest sensitivity may be found in Pacinian corpuscles, which have demonstrated sensitivity to less than about 1 μm skin indentations around approximately 250 Hz to 300 Hz and an effective frequency range from about 60 Hz to 400 Hz. Pacinian corpuscles have a large receptive field and can sense larger vibrations from a distance of on the order of a centimeter away from the receptor. However, smaller vibrations near the 250 Hz frequency of optimal sensitivity produce a response that is localized directly over the Pacinian corpuscle, thereby enabling improved spatial localization with these highly sensitive receptors.

The characteristics of these mechanoreceptors overlap with the known characteristics of microelectromechanical systems (MEMS). Thus, some embodiments include MEMS. Further embodiments include one or more microactuators, each paired with a microamplifier. In some embodiments, a multifunctional actuator-amplifier device is capable of converting small lateral vibration into large vertical vibration that is capable of being sensed by mechanoreceptors, such as Merkel receptors, Meissner's corpuscles, and/or Pacinian corpuscles. In further embodiments, a multifunctional actuator-amplifier device achieves adequate skin indentation and/or spatial resolution while being robust enough to withstand the force of a user's finger or other body part (e.g., forearm, thigh, or face).

### Actuators

According to some embodiments, a multi-functional vibrating device includes an actuator. An actuator can convert a source of energy, such as electric current or pneumatic pressure, into motion. In some embodiments, an actuator can contract and expand in the lateral direction (i.e., in the plane of a horizontal surface). In some embodiments, an actuator can be operated by applying voltages to one or more electrodes positioned on the upper surface of the actuator, on the lower surface of the actuator, and/or the midplane of the actuator. The positioning of the one or more electrodes can depend on the structure of an actuator. In some embodiments, the pattern of the one or more electrodes can be fabricated on an actuator by methods including but not limited to photolithography, other forms of etching, laser machining, ultrasonic drilling, and/or waterjet cutting.

In some embodiments, an actuator is a microactuator. In some embodiments, an actuator is a high speed actuator, such as a piezoelectric plate. A high speed actuator can have a short response time, thus enabling a rapid refresh rate. A piezoelectric plate can be made of a piezopolymer or piezoceramic material such as lead zirconate titanate (PZT). A piezoelectric plate can be a single-layer sheet (e.g., a piezoelectric unimorph) or a two-layer sheet (e.g., a piezoelectric bimorph). The interface between the two layers in a two-layer sheet can either have or not have structural reinforcement. In other embodiments, actuation can be accomplished with a non-piezoelectric actuator.

According to some embodiments, a multi-functional vibrating device is actuated such that it vibrates. The operating frequency of an actuator vibration may be set according to, for example, what is most readily sensed by a user, which typically includes frequencies in the range of approximately 10 Hz to 400 Hz. For some human touch receptors, the optimal frequency has been reported to be 250 Hz. Vibrations can be continuous, pulsed with a duty cycle, or actuated in a particular pattern or rhythm to convey information according to some embodiments.

In some embodiments, the thickness of an actuator (e.g., a piezoelectric plate) can be selected to provide a stiffness sufficient to withstand the force of, for example, a user's finger pressing vertically on the actuator. That is, an expected amount of pressure does not significantly deform and/or deflect the actuator out of plane.

### Amplifiers

According to some embodiments, a multi-functional vibrating device includes an amplifier. The amplifier can convert the relatively small lateral (in-plane) displacement of, for example, an actuator, into a relatively large vertical (out-of-plane) displacement. In some embodiments, this amplified displacement is configured to be, for example, easily sensed by mechanoreceptors in a user's skin.

In some embodiments, an amplifier is a microamplifier. In some embodiments, an amplifier operates using a scissor-like mechanism. Depending on the embodiment, an amplifier may be a conventional scissor mechanism (e.g., linked, folding supports in an X-shaped pattern that is elongated by applying hydraulic, pneumatic, and/or mechanical pressure to the outside of the supports at one end of the mechanism), or the amplifier may have scissor-like functionality. According to some embodiments, a scissor-like mechanism has rigid arms connected to the actuator and to each other by bendable elements that provide some of the same functionality as the hinges in a conventional scissor mechanism. The use of this scissor-like mechanism results in an improved actuator by, for example, reducing the size constraints, which are typically found in competing actuators (e.g., a bending beam mechanism). In some embodiments, an amplifier can make it easier to select an actuator with a thickness sufficient to prevent significant deformation and/or deflection of the actuator under the force applied, for example, by a user, thus resulting in greater robustness.

According to various embodiments, a large number of potential variations to the amplifier architecture have this same scissor-like functionality. An amplifier may have a partial scissor mechanism, in which a hinged structure comprising two rigid bars is attached to the top of an actuator so that the rigid bars form the sides of an upside-down V-shape (i.e., the basic hinged structure).

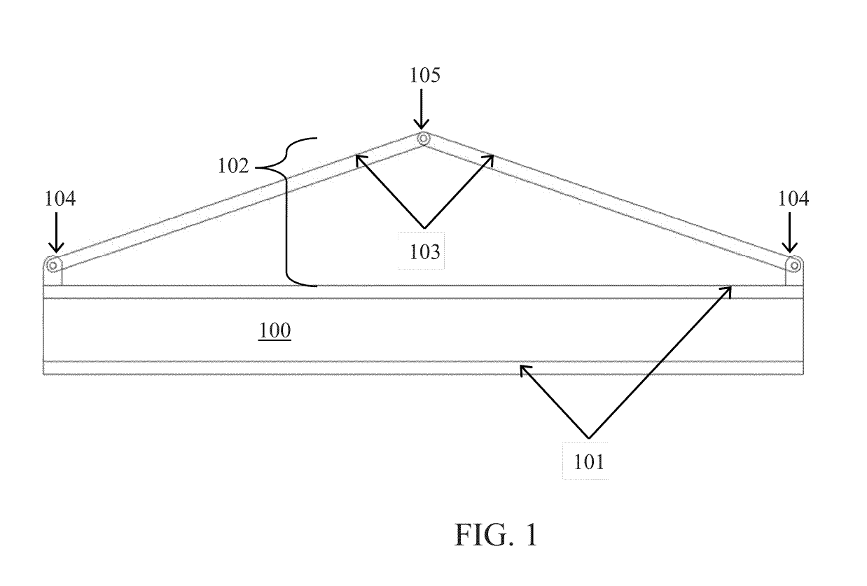

FIG. 1 is a schematic side view of a multi-functional vibrating device with a two-arm amplifier in accordance with some embodiments. FIG. 1 illustrates an actuator 100 (e.g., a piezoelectric plate) and electrodes 101 positioned on both the upper surface and the lower surface of the actuator 100. A hinged structure is attached to a side, e.g., the top side, of the actuator 100 to form an amplifier 102. The amplifier 102 comprises two rigid arms (e.g., bars) 103 that are each connected to the ends of the actuator 100 by hinged connections 104 and are connected to each other by a hinge joint 105. The two rigid arms 103 form the sides of an inverted V-shape. When the actuator 100 contracts (i.e., shortens), the amplifier 102 converts and amplifies the lateral motion to vertical motion so that the hinge joint 105 is pushed upward, away from the horizontal plane. When the actuator 100 expands (i.e., lengthens), the hinge joint 105 is pulled downward, toward the horizontal plane.

In some embodiments, such as embodiments intended for tactile information acquisition, the highest point of an amplifier-actuator mechanism serves to directly contact a user's skin. In further embodiments, an amplifier-actuator mechanism comprises a protrusion or pin, which serves to directly contact a user's skin. A protrusion or pin can be mounted directly on an amplifier, for example, on an arm or a hinge. Alternatively, a protrusion or pin can be mounted on an intervening element (e.g., a flexible membrane suspended above the amplifier-actuator mechanism or another rigid member mounted directly on the amplifier).

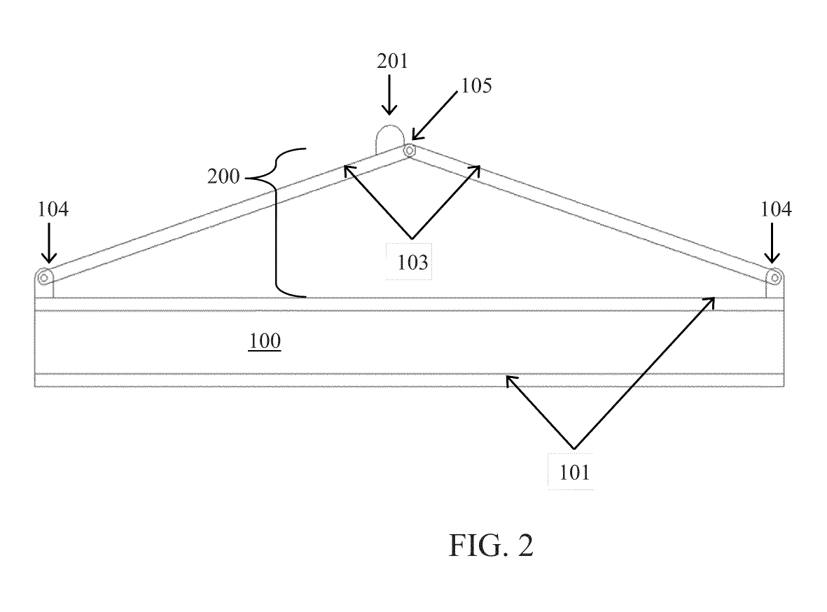

FIG. 2 is a schematic side view of a multi-functional vibrating device with a two-arm amplifier and protrusion in accordance with further embodiments. In addition to the elements illustrated in FIG. 1, the amplifier 200 in FIG. 2 includes a protrusion 201 for embodiments that require, for example, a sensing surface, such as a tactile display. In FIG. 2, the protrusion 201 is a round-tipped pin that is connected to the amplifier 200 near the hinge joint 105 and configured to protrude vertically, particularly when the actuator 100 contracts and the lateral motion is converted to vertical motion of the protrusion upward, away from the horizontal plane. The positioning, shape, and dimensions of the protrusion can be varied according to the embodiment. For example, in embodiments intended for tactile information acquisition, the protrusion can be configured for optimal sensation by mechanoreceptors, such as Merkel receptors, Meissner's corpuscles, and/or Pacinian corpuscles, in the skin of a user's finger or other body part (e.g., forearm, thigh, or face).

According to some embodiments, a hinged structure in an amplifier-actuator mechanism can comprise one or more mechanical hinges (i.e., composed of moving components such as a conventional pin hinge or a magnetic hinge) and/or can be configured to contain materials and structures designed to function like a hinge by, for example, bending elastically at one or more particular locations to allow relative rotation about a fixed axis of rotation. A living hinge is a thin flexible hinge (flexure bearing) made from the same material as the two rigid pieces it connects. It is typically thinned or cut to allow the rigid pieces to bend along the line of the hinge. For example, in some embodiments, the lateral width and/or thickness of an amplifier member may be thinned in a location where a hinge would be so that the strip can bend at that location rather than elsewhere, thus yielding a hinge-like functionality.

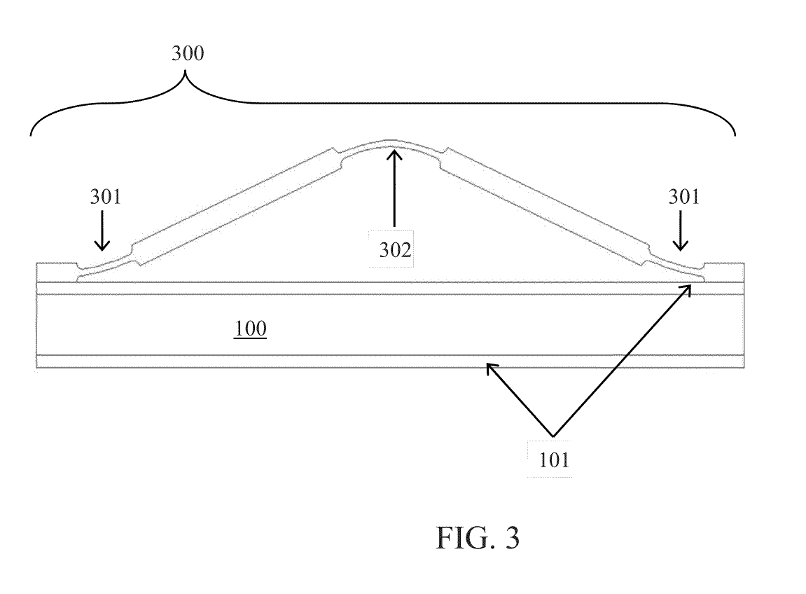

FIG. 3 is a schematic side view of a multi-functional vibrating device with a single-member amplifier in accordance with some embodiments. In addition to an actuator 100 and electrodes 101, FIG. 3 illustrates an amplifier 300 attached to the top of the actuator 100. Instead of two separate rigid arms connected to each other by a hinge joint, the amplifier 300 comprises a single member connected to the ends of the actuator 100. The amplifier member 300 can be configured as a straight or nearly straight member that runs parallel to the horizontal plane of the actuator 100. Alternatively, the amplifier member 300 can be configured to always be bent or bowed out with some angle at one or more living hinges. When the actuator 100 contracts, the amplifier member 300 can convert and amplify the lateral motion to vertical motion by bending or bowing inward (further) at living hinges 301 near the connections to the actuator 100 and bending or bowing outward (further) at living hinge 302 in the center of the amplifier member 300. The living hinge 302 is pushed upward, (further) away from the horizontal plane. When the actuator 100 expands, the living hinge is pulled downward, toward the horizontal plane.

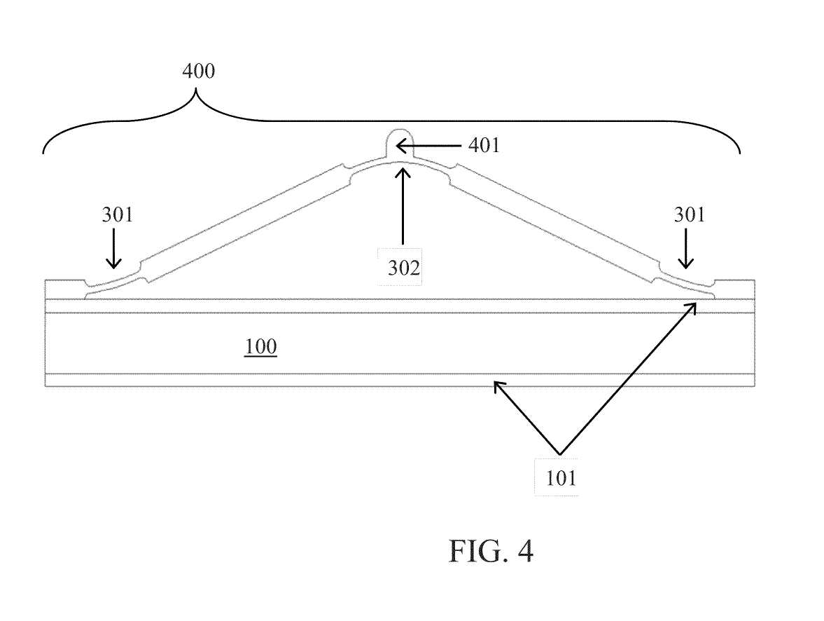

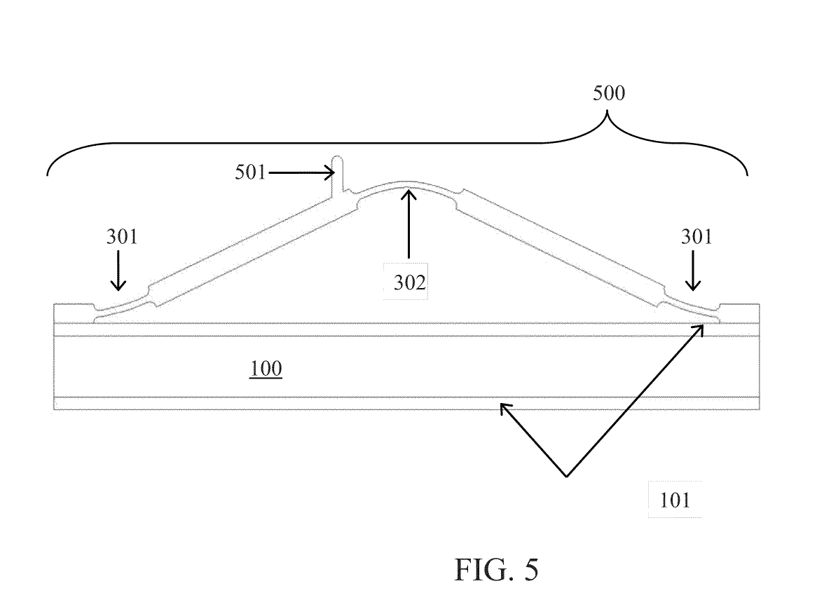

FIG. 4 is a schematic side view of a multi-functional vibrating device with a single-member amplifier and protrusion in accordance with further embodiments. In addition to the elements illustrated in FIG. 3, the amplifier in FIG. 4 includes a protrusion 401 for embodiments that require, for example, a sensing surface, such as a tactile display. In FIG. 4, the protrusion 401 is a round-tipped pin that is connected to the amplifier member 400 on the living hinge 302 and configured to protrude vertically, particularly when the actuator 100 contracts and the lateral motion is converted to vertical motion of the protrusion upward, away from the horizontal plane. The protrusion 401 can be separately formed but connected to the amplifier member 400, or the amplifier member 400 and the protrusion 401 can be formed together as a single member. The positioning, shape, and dimensions of the protrusion can be varied according to the embodiment. For example, the protrusion 401 can be centered on the central living hinge 302. Alternatively, as shown in FIG. 5, a single-member amplifier 500 with living hinges 301, 302 may be formed with or connected to a separately-formed protrusion 501. Instead of being positioned on the central living hinge 302, the protrusion 501 is positioned on a thicker part of the single-member amplifier 500, offset to one side of the central living hinge 302 in accordance with some embodiments.

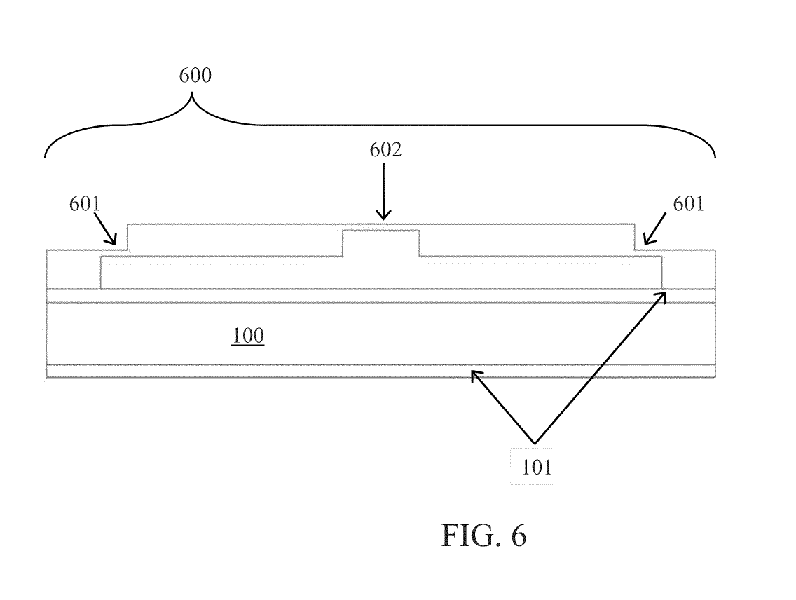

FIG. 6 is a schematic side view of a multi-functional vibrating device with an alternative single-member amplifier 600 in accordance with some embodiments. The amplifier single-member 600 is configured as a straight member that runs parallel to the horizontal plane of the actuator 100 and electrodes 101 and has living hinges 601, 602. FIG. 6 shows the actuator 100 in its rest state; however, when the actuator 100 contracts (i.e., shortens), the amplifier member 600 can convert and amplify the lateral motion to vertical motion by bending or bowing upward at living hinge 602 in the center of the amplifier member 600. Likewise, when the actuator 100 expands (i.e., lengthens), the amplifier member 600 can convert and amplify the lateral motion to vertical motion by bending or bowing downward at living hinge 602 in the center of the amplifier member 600.

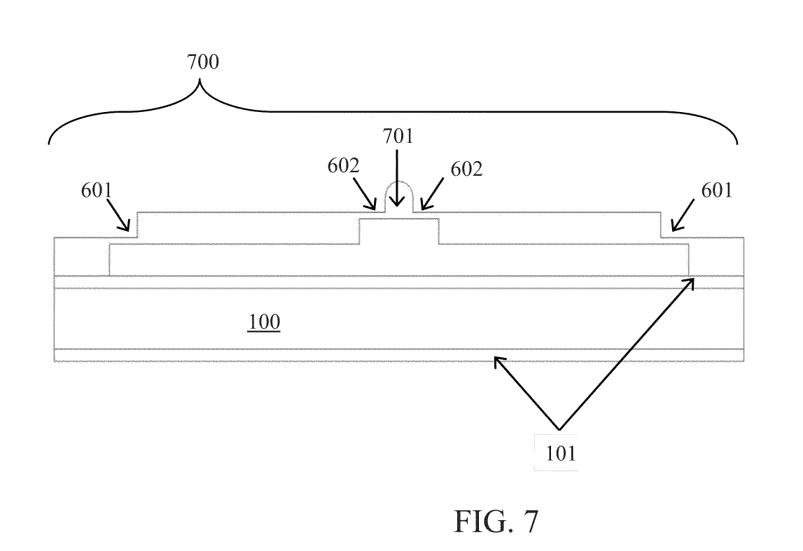

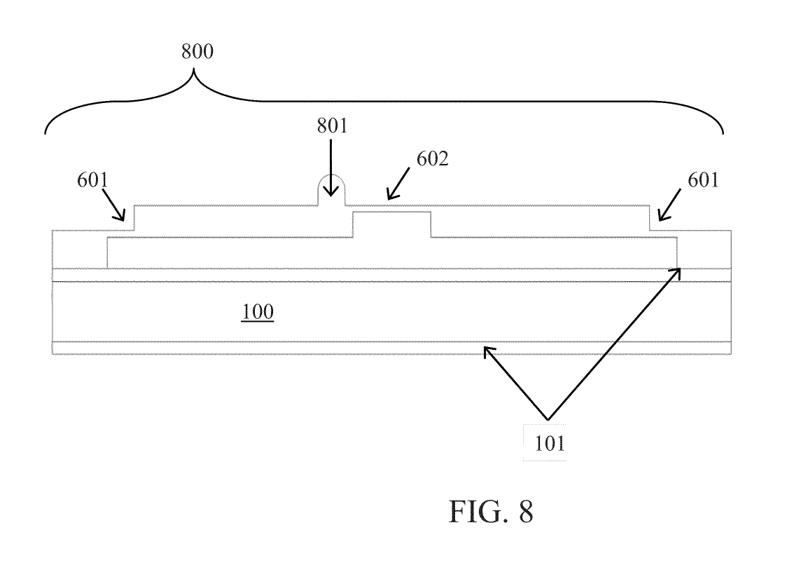

FIG. 7 is a schematic side view of a multi-functional vibrating device with a single-member amplifier and protrusion in accordance with further embodiments. In addition to the elements illustrated in FIG. 6, the amplifier in FIG. 7 includes a protrusion 701 for embodiments that require, for example, a sensing surface, such as a tactile display. In FIG. 7, the protrusion 701 is a round-tipped pin that is connected to the amplifier member 700 on the living hinge 602 and configured to protrude vertically. The protrusion 701 can be separately formed but connected to the amplifier member 700, or the amplifier member 700 and the protrusion 701 can be formed together as a single member. The positioning, shape, and dimensions of the protrusion can be varied according to the embodiment. For example, the protrusion 701 can be centered on the central living hinge 602. Alternatively, as shown in FIG. 8, a single-member amplifier 800 with living hinges 601, 602 may be formed with or connected to a separately-formed protrusion 801. Instead of being positioned on the central living hinge 602, the protrusion 801 is positioned on a thicker part of the single-member amplifier 800, offset to one side of the central living hinge 602 in accordance with some embodiments.

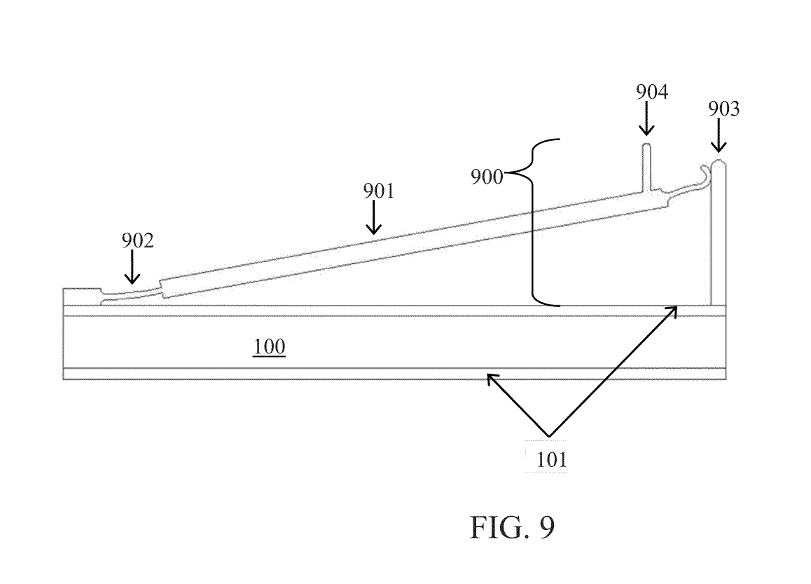

In some embodiments, one or more rigid arms of an amplifier can be configured to slide against a wall that protrudes from an actuator to convert the lateral motion of the actuator into vertical motion. Functionally, the wall replaces the central hinge, and a single arm with a hinged connection to the actuator is sufficient to amplify the actuation as vertical displacement. FIG. 9 is a schematic side view of a multi-functional vibrating device with a single-arm amplifier and protrusion in accordance with some embodiments. As FIG. 9 illustrates, a hinged structure is attached to the top of the actuator 100 and electrodes 101 to form an amplifier 900. The amplifier 900 comprises a rigid arm (e.g., a bar) 901 that is connected to one end of the actuator 100 with a hinged connection 902. The free end of arm 901 is configured to contact a rigid, vertical wall 903 that is connected to and protrudes from the opposite end of the actuator 100. When the actuator 100 contracts, the free end of arm 901 moves upward, away from the horizontal plane, along a side of the wall 903, thereby converting and amplifying the lateral motion to vertical motion. When the actuator 100 expands (i.e., lengthens), the free end of arm 901 can move back down the side of the wall 903, toward the horizontal plane. In addition, the amplifier 900 includes an optional protrusion 904, for embodiments that require, for example, a sensing surface, such as a tactile display. In FIG. 9, the protrusion 904 is a round-tipped pin that is connected to the amplifier arm 901 and configured to protrude vertically. The protrusion 904 can be separately formed but connected to the amplifier arm 901, or the amplifier arm 901 and the protrusion 904 can be formed together as a single member. The positioning, shape, and dimensions of the protrusion can be varied according to the embodiment.

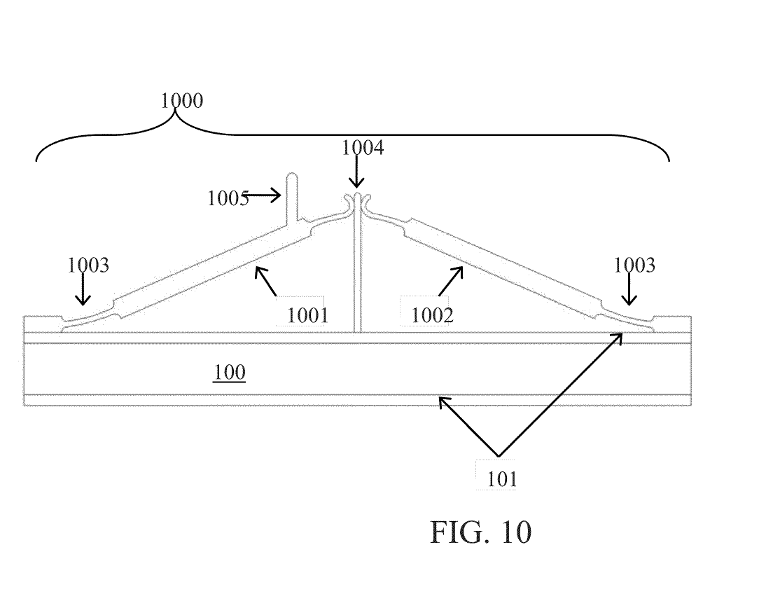

FIG. 10 is a schematic side view of a multi-functional vibrating device with a two-arm amplifier and protrusion in accordance with further embodiments. As FIG. 10 illustrates, two hinged structures are attached to the top of the actuator 100 and electrodes 101 to form an amplifier 1000. The amplifier 1000 comprises two rigid arms (e.g., bars) 1001, 1002 that are connected to opposite ends of the actuator 100, each with a hinged connection 1003. The free ends of the arms 1001, 1002 are configured to contact a rigid, vertical wall 1004 that is connected to and protrudes from the center of the actuator 100. When the actuator 100 contracts, the free end of each arm 1001, 1002 moves upward, away from the horizontal plane, along opposite sides of the wall 1004, thereby converting and amplifying the lateral motion to vertical motion. When the actuator 100 expands (i.e., lengthens), the free end of each arm 1001, 1002 can move back down the sides of the wall 1004, toward the horizontal plane. In addition, the amplifier 1000 includes an optional protrusion 1005, for embodiments that require, for example, a sensing surface, such as a tactile display. In FIG. 10, the protrusion 1005 is a round-tipped pin that is connected to one amplifier arm 1001 and configured to protrude vertically. The protrusion 1005 can be separately formed but connected to an amplifier arm, or an amplifier arm and the protrusion 1005 can be formed together as a single member. The positioning, shape, and dimensions of the protrusion can be varied according to the embodiment.

In some embodiments, an amplifier comprises two rigid arms, which form an X-shape having a hinge at its center, thereby increasing the possible vertical displacement, for example, by two times that of the basic hinged structure. In further embodiments, an amplifier comprises two rigid arms forming an X-shape with a hinge at its center (alternatively, the two rigid arms forming the X-shape can be connected with anything having the functionality of a hinge, such as a mechanical or living hinge, or the two rigid arms may cross without being connected), as well as two rigid arms connected to each other by a hinge and forming an upside-down V-shape on top of the X-shape. The end of each arm in the upside-down V-shape is connected to the end of an arm in the X-shape via hinged connections, thereby increasing the possible vertical displacement, for example, by three times that of the basic hinged structure of FIG. 1. In further embodiments, an amplifier comprises 2×N rigid arms, where N is a whole number, to form N X-shapes, each with a hinge at its center, stacked on top of each other in what can be referred to as a multiple-scissor mechanism or a stacked-scissor mechanism. Alternatively, an amplifier comprises 2×N rigid arms to form (N−1) X-shapes, each with a hinge at its center, stacked on top of each other and topped off by an upside-down V-shape in what can be referred to as a multiple-scissor-like mechanism or a stacked-scissor-like mechanism.

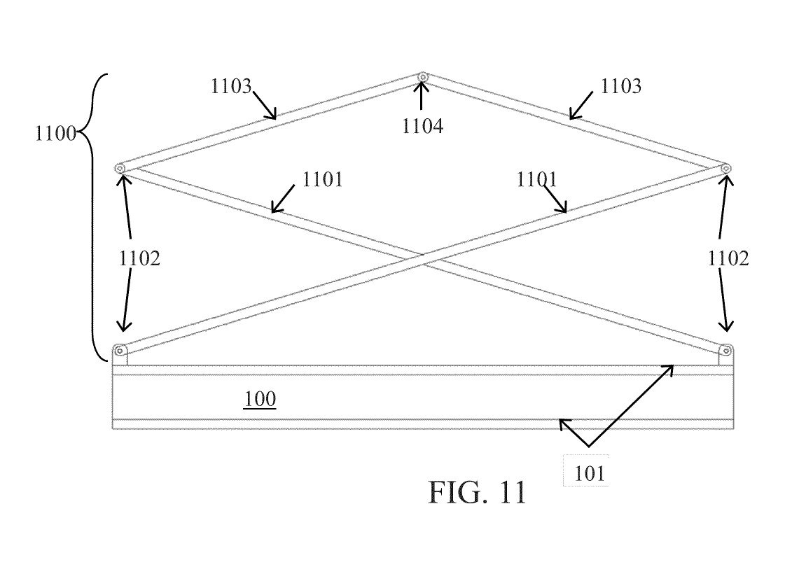

FIG. 11 is a schematic side view of a multi-functional vibrating device with a four-arm amplifier in accordance with some embodiments. As FIG. 11 illustrates, a hinged structure is attached to the top of the actuator 100 and electrodes 101 to form an amplifier 1100. The amplifier 1100 comprises a first level of two rigid arms (e.g., bars) 1101 that are each connected to the ends of the actuator 100 by hinged connections 1102. The first level of two rigid arms 1101 are not connected to each other but do cross each other to form an X-shape when the actuator 100 contracts. Alternatively, the first level of two rigid arms 1101 can be connected to each other using a central hinge. In other embodiments, any or all levels of scissor-like mechanisms can be implemented with or without a connecting hinge. The amplifier 1100 further comprises a second level of two rigid arms 1103 that are each connected to the ends of the first level of two rigid arms 1101 by hinged connections 1102 and are connected to each other by a hinge joint 1104. When the actuator 100 contracts, the amplifier 1100 converts and amplifies the lateral motion to vertical motion so that the hinge joint 1104 is pushed upward, away from the horizontal plane. When the actuator 100 expands (i.e., lengthens), the hinge joint 1104 is pulled downward, toward the horizontal plane.

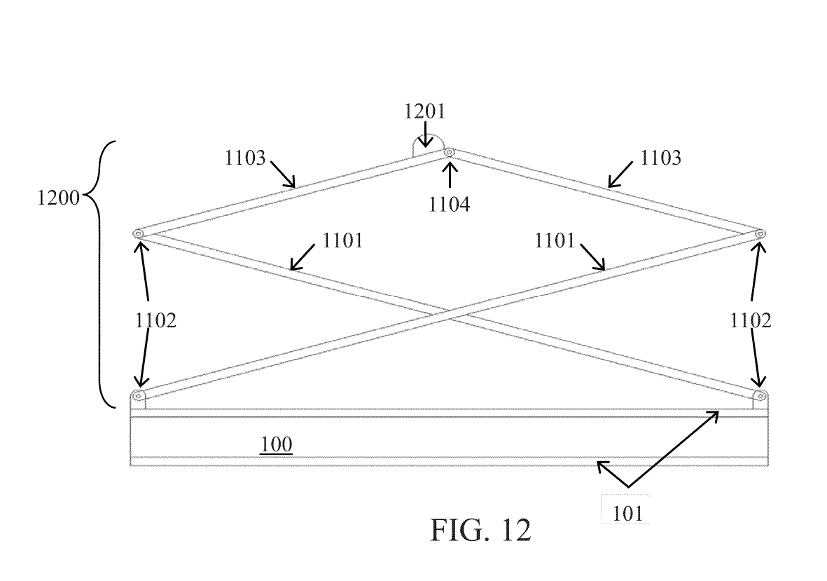

FIG. 12 is a schematic side view of a multi-functional vibrating device with a four-arm amplifier and protrusion in accordance with further embodiments. In addition to the elements illustrated in FIG. 11, the amplifier 1200 in FIG. 12 includes a protrusion 1201 for embodiments that require, for example, a sensing surface, such as a tactile display. In FIG. 12, the protrusion 1201 is a round-tipped pin that is connected to the second level of two rigid arms 1103 near the hinge joint 105 and configured to protrude vertically, particularly when the actuator 100 contracts and the amplifier 1200 converts the lateral to vertical motion of the protrusion 1201 upward, away from the horizontal plane. The positioning, shape, and dimensions of the protrusion can be varied according to the embodiment.

According to some embodiments, the amplitude of the vertical (out-of-plane) displacement is many times greater than the amplitude of the lateral (in-plane) displacement. In some embodiments, if the initial angle between the horizontal plane and the amplifier is near zero degrees, then the vertical displacement can be more than 40 times greater than the horizontal displacement. For example, if a 3-mm-long piezoelectric extension actuator has a lateral displacement of 0.3 μm, the amplified vertical displacement can be more than 12 μm according to some embodiments. More generally, the ratio of vertical displacement to horizontal displacement is given by the cotangent of the angle between the actuator and the amplifier arm.

Although the orientation of a multi-functional vibrating device is described herein as an actuator with an amplifier positioned above to convert lateral motion to vertical motion, amplifier elements may be located on any one side (e.g., top or bottom) of an actuator or on more than one side (e.g., top and bottom) of an actuator according to various embodiments.

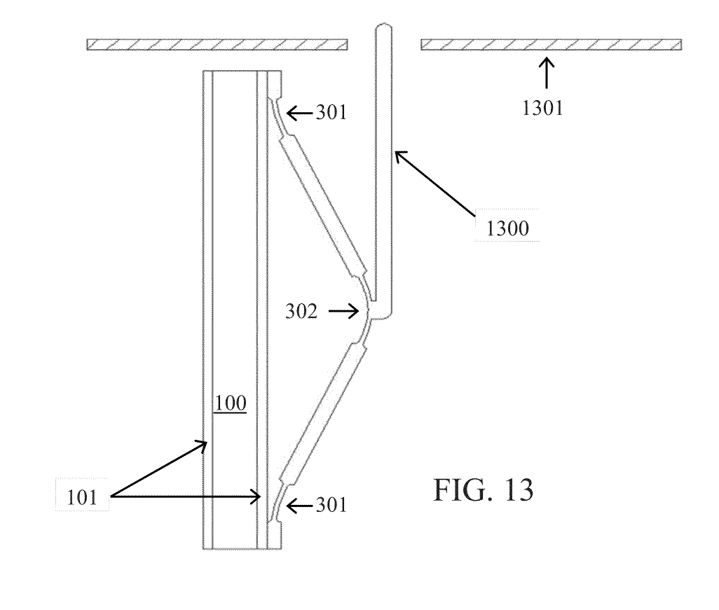

In some embodiments, such as embodiments intended for tactile information acquisition, the amplified motion may also be used to create a shear (side-to-side) excitation, for example, along a user's skin. In such embodiments, each actuator beam is oriented vertically with respect to the substrate, so that the amplifier elements produce pronounced side-to-side motion. This side-to-side motion can be conveyed to the upper surface where a user can feel it via a protruding pin that extends from the point of maximum motion (e.g., the central hinge in a basic hinged structure). For example, FIG. 13 is a schematic side view of a multi-functional vibrating device with a single-member amplifier oriented for shear excitation in accordance with some embodiments. FIG. 13 illustrates an actuator 100 and electrodes 101, which are oriented vertically instead of in the horizontal plane. An amplifier comprising a single member is mounted to the ends of the actuator 100. The amplifier can be configured as one or more straight or nearly straight members that run parallel at rest to the vertical plane of the actuator 100. Alternatively, the amplifier can be configured as one or more bent or bowed members with some angle at rest at one or more living hinges. When the actuator 100 contracts, the amplifier member can convert and amplify the vertical motion to lateral motion by bending or bowing inward (further) at living hinges 301 near the connections to the actuator 100 and bending or bowing outward (further) at living hinge 302 in the center of the amplifier member. The living hinge 302 is pushed (further) away from the vertical plane. When the actuator 100 expands, the living hinge is pulled back toward the vertical plane. Importantly, FIG. 13 illustrates a protrusion 1300. The protrusion 1300 is a long, round-tipped pin that is connected to the amplifier member on the living hinge 302 and configured to protrude vertically, for example, through an aperture in a device cover 1301. When the actuator 100 contracts, the vertical motion is converted to side-to-side motion of the protrusion 1300. The protrusion 1300 can be separately formed but connected to the amplifier member, or the amplifier member and the protrusion 1300 can be formed together as a single member. The positioning, shape, and dimensions of the protrusion can be varied according to the embodiment.

### Arrays of Vibrating Devices

In some embodiments, amplifiers can enable the use of an array of multi-functional vibrating devices with more than one actuator, smaller actuators, and/or a denser arrangement of actuators, thus resulting in greater versatility and compactability and higher resolution.

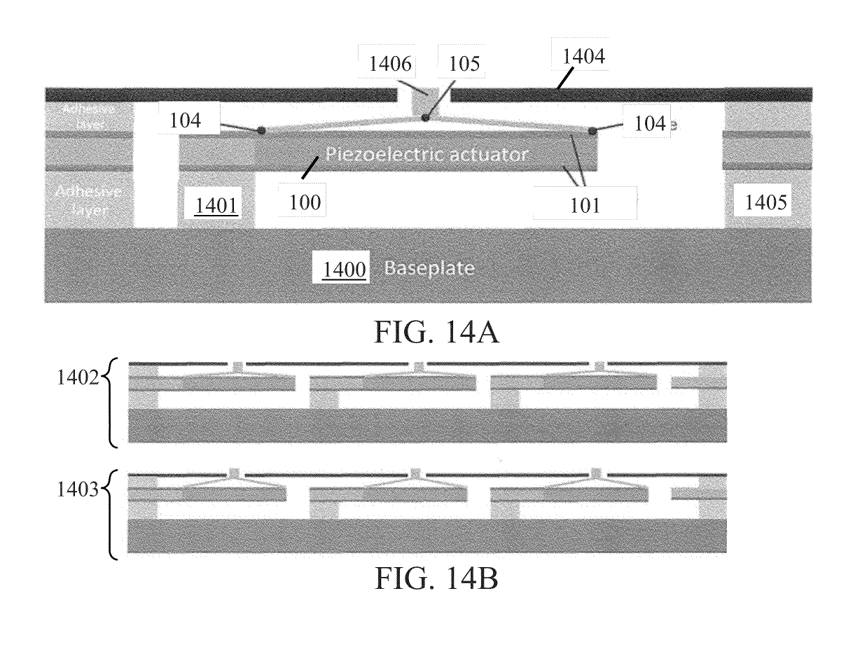

According to some embodiments, one or more vibrating devices can be mounted on a horizontal base, including but not limited to a printed circuit board baseplate, from which solder connections may be made; a silicon chip, from which connections to individual memory elements may be made; or any other type of base (e.g., a custom chip carrier) that allows electrical connections to be made. Each actuator can be supported by, for example, a center post, one or more tethers anchored at the center of the tactel actuator beam, or by a fixed support at one end of the tactel actuator beam (i.e., a cantilever). FIG. 14A is a schematic side view of a vibrating device mounted on a base 1400 using a fixed support 1401 according to some embodiments. FIG. 14B is a schematic side view of two series 1402, 1403 of vibrating devices mounted with fixed supports on a base with electrical connections according to further embodiments.

According to some embodiments, the top of one or more vibrating devices is covered by a horizontal cover or cap plate. According to some embodiments, a cap plate has an array of one or more holes or perforations lining up with the protrusions or pins of the one or more vibrating devices. The cap plate is positioned such that upon actuation, the lateral motion of each actuator is converted and amplified, pushing each protrusion upward and to or through the one or more holes in the cap plate. As shown in FIGS. 14A-14B, a cap plate 1404 is held by a series of supports 1405 to cover one or more vibrating devices in accordance with some embodiments. In series 1402 of FIG. 14B, each vibrating device is in an un-actuated rest position where the protrusions do not extend beyond the cover plate and, in embodiments for tactile information acquisition, a user would not feel any vertical motion. In alternative embodiments, the protrusions may extend at least partially beyond the cover plate at rest but not be vibrating. In series 1403 of FIG. 14B, each vibrating device is in an actuated position where the protrusions extend through the perforations in the cover plate and a user could feel vibratory motion in the associated tactels.

The layout shape and spacing between vibrating devices in an array may vary. In some embodiments, large extensional motions are produced with sufficient length in only one dimension. According to these and other embodiments, two or more vibrating devices may be arranged as, for example, a rectilinear two-dimensional array or an offset two-dimensional array. It may be desirable to minimize the overall size of the array by making each vibrating device narrower than it is long.

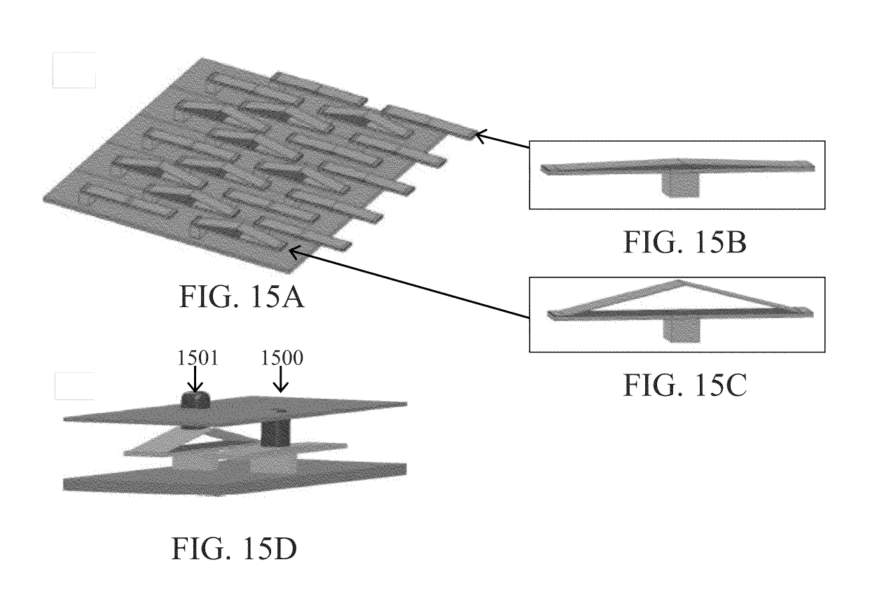

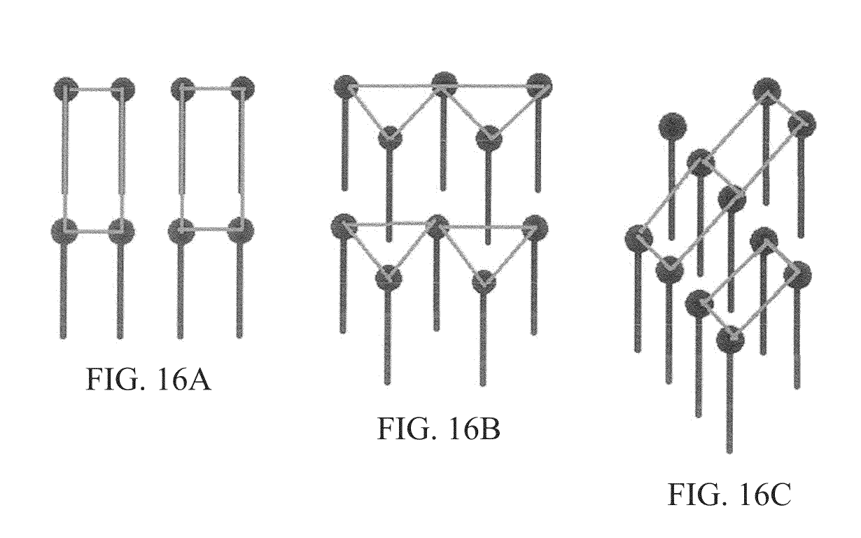

FIG. 15A is a schematic view of an array of vibrating devices according to some embodiments. Although each vibrating device has one long dimension, it can be patterned as an offset array of more than one vibrating device. The offset array ensures that the tactel-to-tactel spacing is more uniform in the two in-plane directions. FIGS. 16A-16C are schematic top views of different layouts for an array of vibrating devices in accordance with some embodiments. The circles represent fixed supports or anchors of vibrating devices, and the heavy lines represent actuator beams. In FIG. 16A, the array layout is rectilinear according to some embodiments. The rectangles indicate the periodicity of the array. In other embodiments, offset array layouts are used to reduce tactel-to-tactel spacing. In FIG. 16B, the array layout is offset according to some embodiments, and the triangles indicate the periodicity of the array. In FIG. 16C, the array layout is offset according to alternative embodiments, and the rectangles indicate the periodicity of the array. For the case of actuator beams that are 2.5 mm long and 400 microns wide, the array of FIG. 16A would have a tactel-to-tactel spacing of just over 2.5 mm in the vertical direction and just over 400 microns (0.4 mm) in the horizontal direction. For example, in the array of FIG. 16B, this can be improved to just over 800 microns (0.8 mm) in the horizontal direction and just over 1.3 mm in the diagonal direction, depending on the exact offset used in the array design.

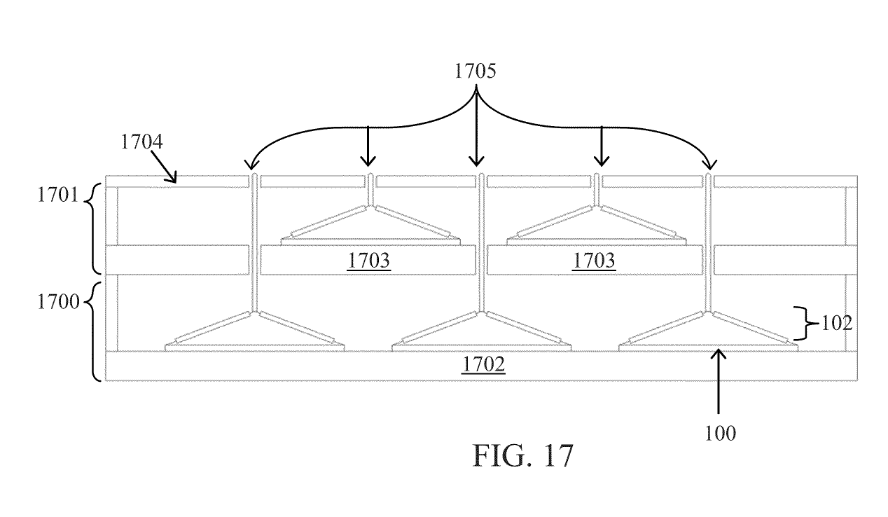

According to some embodiments, two or more layers of the vibrating devices described above may be used to obtain a higher density of vibrating elements. For example, FIG. 17 is a schematic side view of a two-layer array of vibrating devices in accordance with some embodiments. As FIG. 17 illustrates, a first array of devices 1700 may be layered with a second array of devices 1701. The first array of devices 1700 is mounted on a base 1702, the second array of devices 1701 is mounted on a base 1703, and the two-layer array of devices is topped by a cover 1704. Both the base 1703 and the cover 1704 can be configured with access holes or perforations. Each vibrating device is topped by its own protrusion or pin 1705. The protrusions 1705 on the lower-layer, first-array devices are configured to be longer than the protrusions 1705 on the higher-layer, second-array devices so that the protrusions 1705 are equally capable, for example, of protruding through access holes or perforations in the base 1703 and the cover 1704 upon actuation. In other embodiments, more than two arrays of vibrating devices can be layered on an equal number of bases. Both the bases and a cover can be configured with access holes or perforations so that the protrusion on each vibrating device (configured to have a length commensurate with its level) is equally as capable as the other protrusions, for example, of protruding through the cover upon actuation.

According to some embodiments, electrical contact can be made with each actuator in an array so that, for example, individual devices may be actuated to convey information. In some embodiments, a piezoelectric plate actuator (e.g., a piezoelectric unimorph or a “y-poled” piezoelectric bimorph) is polarized such that the plate is always polarized in the same direction throughout its thickness. For example, electrodes are located on the upper and lower surfaces of the plate. One or more electrodes on one side (i.e., upper or lower) can be actuated with a common voltage (e.g., ground). One or more electrodes on the opposite side (i.e., lower or upper) can be actuated with individually varying voltages, a unique voltage for each device. The opposite side can be configured to include a way to send separate actuating signals to each device. In some embodiments, separate actuating signals can be transmitted using one current flow path per device. In other embodiments, separate actuating signals can be transmitted using an underlying memory circuit in which each memory element drives the behavior of each device. In alternative embodiments, a piezoelectric plate actuator is an “x-poled” bimorph, which is polarized so that the two layers are polarized in the opposite direction. In further embodiments, electrodes can be located on the upper and lower surfaces and at the midplane of the plate. One or more electrodes at the midplane can be actuated with a common voltage (e.g., ground). One or more electrodes on the upper and lower surfaces can be patterned to enable each device to be driven by its own unique voltage signal.

As shown in FIGS. 15A-15D, vibrating devices can be individually actuated to convey information. For example, unique current flow paths can be activated or unique voltages can be applied to the array in FIG. 15A that, for example, does not actuate some vibrating devices (e.g., the device shown in FIG. 15B or device 1500 in FIG. 15D) but does actuate other vibrating devices (e.g., the device shown in FIG. 15C or device 1501 in FIG. 15D).

Tactile Displays with Vibrating Devices

In accordance with some embodiments, a tactile display comprises an array of vibrating devices, which are analogous to pixels in a visual display. The term “tactel” is used in this disclosure to mean one of these vibrating devices. When a tactel is “turned off,” it remains stationary in its rest position. When a tactel is “turned on,” it vibrates up and/or down (i.e., out of plane) from its rest position. In some embodiments, a user feels the displacement of a tactel on his or her skin. In some embodiments, tactile displays are optimized for use with fingertips. However, for some people this is not practical (e.g., for diabetics who may suffer from reduced fingertip sensitivity from monitoring their glucose levels), and some embodiments are optimized for use on other regions of skin such as the forearm, thigh, or neck.

According to some embodiments, a user is able to sense each individual tactel. The user may feel the peak of a hinged amplifier directly. Alternatively, the user may feel a protrusion (e.g., a round-tipped pin) directly connected to the amplifier (e.g., directly or indirectly mounted on the amplifier, or formed integral with the amplifier at a central hinge, on an arm, or elsewhere) or indirectly connected to the amplifier through an intervening element. In further embodiments, multiple tactels can be turned on and off independently to create patterns of vibration that a user can decode. For example, tactels can be actuated to create an area of stimulation that has a particular size or shape or to create a sensation of motion as tactels are turned on in sequence.

In some embodiments, a cover is used to cover and/or protect the tactel elements. The cover may be perforated so that at least one protrusion or pin extends beyond the cover to allow a user to feel displacement or vibration of the associated tactel. In some embodiments, the cover prevents a user from feeling the topography of the tactel array as a whole. In further embodiments, a cover may consist of or the perforations in a cover plate may be covered by a thin, deformable membrane (i.e., a membrane that does not substantially limit the displacement or vibration). The membrane may be utilized to further protect the internal components (e.g., the tactel elements) from dust, liquids, or other environmental hazards.

According to some embodiments, hardware for a tactile display can be a high-resolution array of small (e.g., 1 mm²), rapidly-updatable, vibrating tactels (e.g., 30 to 100 tactels on a side, or 1,000 to 10,000 total tactels) for an overall display area on the order of that of a smartphone or tablet. Each tactel is driven by an extension actuator that lengthens and contracts in one direction when a voltage is applied between its upper and lower surfaces, and its motion is converted to a perpendicular direction and amplified by an amplifier with a scissor-like mechanism as described above according to some embodiments. For example, a 0.5-μm lateral motion can result in more than 20-μm vertical motion, which is well within the sensitivity of human fingertips at appropriate frequencies. In some embodiments, actuators in an array are driven independently, for example, with an oscillating voltage that causes the attached pins to vibrate up and down. A user places his or her finger, for example, over the array and senses the vibrations of the pins. In some embodiments, by turning the pin vibrations on and off in a synchronized fashion, the tactile display device is designed to convey information by means other than pure spatial recognition, such as the sensation of motion across the user's skin, the tapping of rhythms on, for example, the user's fingertips, and variations in the amplitudes and operating frequencies of the tactels. According to some embodiments, one or more tactels in a display also may be used to code information about how each tactel is actuated (e.g., actuation frequency, duty cycle, rhythm, timing, sequence, and/or pattern).

Part of the appeal of a smartphone or tablet for a sighted person is its intuitive ease of use—even a pre-literate child can use one—along with its ability to provide a rich diversity of information and entertainment with excellent information privacy. To achieve the equivalent functionality for a person with permanently or temporarily impaired vision, some embodiments of a tactile display device are designed to be intuitive (e.g., even for users who are not braille-literate), versatile (e.g., flexible and adaptable to different functions/applications), and private (e.g., similar to what can be obtained with a smartphone or tablet).

Even if all visually-impaired children were taught to read braille, many people whose vision becomes impaired in adulthood do not choose to invest the time required to decode the static patterns of braille. A refreshable but purely statically-sensed braille display can be expected to face the same challenges in adoption. To encourage widespread adoption, some embodiments of a tactile display device are designed to minimize the need for training such that the required training for those embodiments is orders of magnitude less than what is required to learn braille.

In addition to the two spatial dimensions, some embodiments are configured to vary actuations rapidly in time to create rhythms or sensations of motion. These combinations of rhythm, spatial pattern, and motion are known as “tactons” (i.e., spatial/temporal patterns of actuation that represent something). For example, if the user's destination is in the two o'clock direction, the display could create a traveling line of actuation under the user's fingertips in that direction. When another person enters the room, it could be signaled by a particular rhythm of actuation. Or, an upcoming high obstacle could be signaled by a dramatic, hard-to-miss actuation that travels outward from the center like the explosion of fireworks. These are only a small sample of the number and types of tactons that may be created to code information of interest. The addition of time-varying signals makes using some embodiments more intuitive. In addition, some embodiments remain applicable for static display purposes, such as for reading a graph from an exam.

Precedents for this type of intuitive information transfer show that it can be highly effective. For example, low-resolution arrays of vibrating elements can be worn on the torsos of military pilots to combat spatial disorientation under poor visibility and high accelerations. In addition, experiences in everyday life tell us that it is much easier to discern directional motion (e.g., something brushing across the skin) or rhythm (e.g., different mobile phone alerts) than it is to discern spatial patterns (e.g., identifying braille letters or identifying by touch an object that is hidden inside a box).

In addition to conveying information to individuals with low or impaired vision, embodiments may convey information through the sense of touch to any individual for whom obtaining tactile information provides an advantage. Some embodiments advantageously allow information to be conveyed silently, in darkness, and/or to complement information provided through visual and auditory channels. Embodiments may be valuable for military applications, in which a tactile display is, for example, strapped to part of a soldier's body, incorporated into uniforms, or integrated with existing military hardware (e.g., weapons or vehicle/aircraft control sticks). Embodiments also may be useful for civilian applications, such as alerting a driver to an upcoming road hazard.

### EXAMPLES

Those skilled in the art will recognize, or be able to ascertain, using no more than routine experimentation, numerous equivalents to the specific substances and procedures described herein. Such equivalents are intended to be encompassed in the scope of the claims that follow the examples below.

The literature results on tactile sensitivity are limited, provide a spread of values for threshold and resolution, and can be specific to the testing methodology. Furthermore, sensing thresholds vary from person to person; thresholds for extracting useful information will depend on the type of signal being conveyed (spatial, spatio-temporal, rhythm, etc.); and users' perceptions of the psychophysical dimensions of a sensation (rough/smooth, hard/soft, etc.) also vary among individuals. This variation between individuals and literature reports introduces some uncertainty into the design of the system and even into the definition of its necessary specifications. Therefore, while it is challenging to create a universal set of optimal specifications for a tactile display, a baseline set of requirements was created for a tactile display according to some embodiments. These requirements can be refined through user testing to ensure that the final design accommodates person-to-person variations but is not so over-designed as to dramatically increase cost. The requirements can be chosen based on the sensing characteristics of fingertips; it is relatively simple to adapt a high resolution design for use on other areas of skin instead, albeit at a lower resolution.

According to some embodiments, a tactile display according to the following high-level operational requirements and design requirements offers a high degree of functionality as compared with competing approaches. Analytical models were used to describe the performance of the tactile display architecture in some embodiments as a function of these operational and design parameters.

Tactel size: In some embodiments, the tactels are designed for a minimum area of about 1 mm², which is comparable to the smallest spatial resolution of human mechanoreceptors. A tradeoff exists between tactel size and the achievable amplitude of motion; larger tactels can produce larger vibrations. In some embodiments, tactel sizes range from approximately 1 mm² to 4 mm², with some tactels created at larger sizes (e.g., 10 mm² or even greater) for display. Sensing performance over a range of sizes can be used to refine a tactile display according to some embodiments.

Vibrational frequency: Smaller tactels produce relatively smaller vibrations, which can only be sensed at high frequencies. The operating frequency must be high to have a high resolution display of compact tactels manufactured from a single piezoelectric layer without assembly of separate actuators in accordance with some embodiments. In some embodiments, the target frequency range for testing is from approximately 30 Hz to 300 Hz, with optimum sensitivity expected near 250 Hz. In further embodiments, resonant drive can be used to minimize drive voltage requirements.

Vibrational amplitude: In some embodiments, the minimum amplitude specification is selected to be about 5 μm (i.e., more than 5 times above the sensitivity limit for Pacinian corpuscles near 250 Hz). However, embodiments may be configured to achieve a range of vibration amplitudes from a lower limit of about 5 μm up to a range of about 50 μm for larger tactels. Such larger amplitudes are well above the sensitivity for Meissner's corpuscles, and near the limit for high-resolution Merkel cell receptors to better enable some embodiments.

Resistance to applied loads: According to some embodiments, a user will apply a load to the display while “reading” its output. The tactels can be configured to have sufficient structural stiffness to prevent any adverse effects due to these loads, such as reduced skin indentation due to tactel deflection under load. The extensional actuator also can be configured to be powerful enough to overcome the axial forces that are conveyed to the actuator beam from the user's fingertips via the amplification mechanism. Finally, the stresses under load can be configured to remain below the failure stresses of the actuator and amplifier material(s).

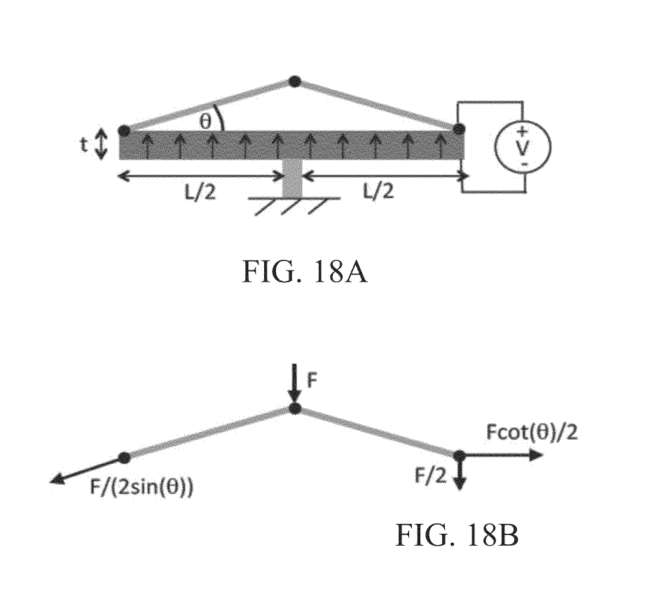

FIG. 18A illustrates the actuator and amplifier geometry of a tactel according to some embodiments. When a tactel is actuated, its actuator contracts and extends. In some embodiments, an actuator layer is cut from a lead zirconate titanate (PZT) piezoceramic sheet with a thickness of a few hundred microns. This large thickness enables both adequate actuation and robustness against user-applied loads. Sheets of this thickness are readily available from commercial suppliers (e.g., Piezo Systems, Inc. (Woburn, Mass.)), and their electrodes and overall geometries can be defined using, for example, laser ablation or waterjet cutting. As shown in FIG. 18A, the important parameters of the actuator are its length L, width w, thickness t, whether the piezoelectric material is x-poled or y-poled (i.e., poled in antiparallel or parallel layers), and the voltages V under which it operates.

According to some embodiments, the amplifier is a scissor or scissor-like mechanism comprising two relatively rigid bars connected by what is effectively a hinge. The rigid bars are anchored to the two ends of the actuator beam and to each other in the center, so that they form an upside-down V shape. When the actuator contracts, the center of the V rises up. When the actuator extends, the center of the V drops down. As shown in FIG. 18A, the most important amplifier parameter is the angle θ that the bars make with the horizontal plane when no voltage is applied. The angle θ determines not only the amplification factor (i.e., the ratio of vertical motion amplitude to horizontal motion amplitude), but also the way that vertical loads applied to the tactel are conveyed to the actuator. FIG. 18B is a diagram of horizontal and vertical loads from a user according to some embodiments. Larger values of angle produce smaller axial forces along the actuator, whereas smaller values of angle produce larger axial forces along the actuator. In some embodiments, the size scale is too small for a conventional pinned hinge. Implementation of the hinges can instead be accomplished using living hinges, locally thinner points in a bending beam that reduce the bending stiffness and localize bending at the desired hinge position. Such living hinges may be created using, for example, 3D printing, injection molding, screen-printing, or attachment of a laminated sheet stamped to form flexural hinges.

In some embodiments, a complete tactel comprises the mechanical amplifier mounted on top of the actuator. In theory, an actuator may be mounted to a base at any single contact point, including at one end of the actuator, in the center of the actuator, or at any other desired location along the actuator. In some embodiments, the actuator is mounted on a central support so that it may expand and contract as necessary while minimizing the protruding beam length. This configuration can reduce or eliminate side-to-side motion of the amplifier's peak and increase the vertical stiffness of the protruding actuator beams to minimize vertical deflection. In some embodiments, protrusions or pins are mounted on the tactels so that they protrude through the cap plate over the display. Protrusions or pins can be created using, for example, 3D printing, injection molding, metal stamping, or screen-printing in 3D. A flexible cover can also be integrated to prevent entry of dust or moisture according to some embodiments.

Conventional displays use piezoelectric bending beam actuators; however, piezoelectric bending beams with the necessary performance do not scale well to the small tactel sizes achieved by some embodiments. For example, the bending beams that drive refreshable braille readers have lengths on the scale of, for example, about an inch. To form arrays of protrusions or pins from these long bending beams, the actuators must be overlapped in a vertical stack, at the cost of increased assembly expense and system size.

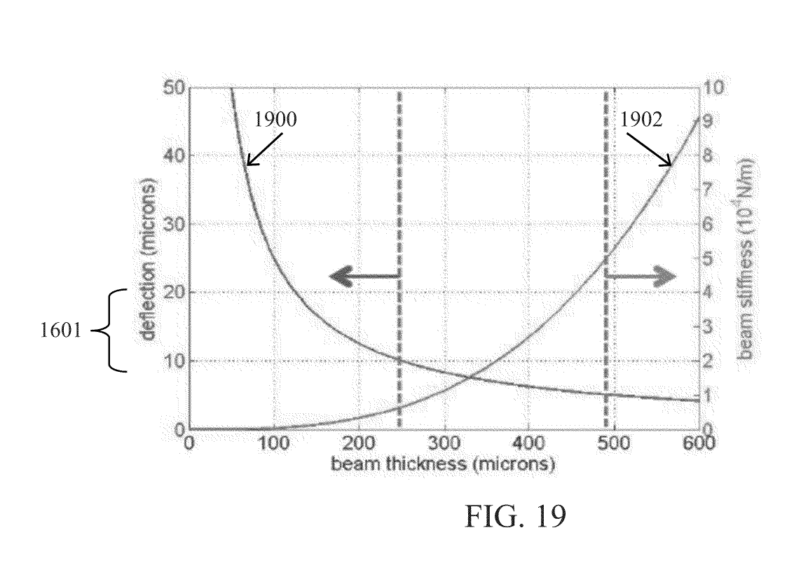

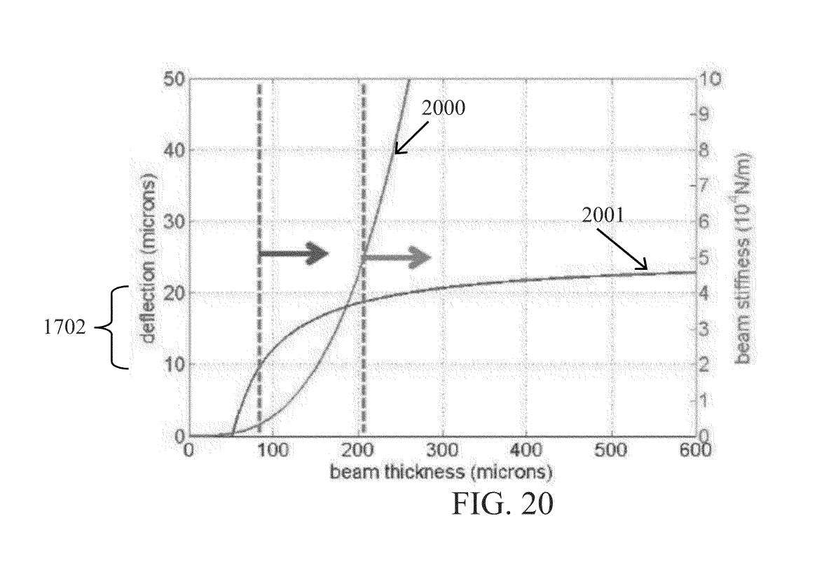

FIGS. 19-20 are plots illustrating the advantages of some embodiments as compared with bending beams, specifically a 2.5-mm-long tactel compared with a 2.5-mm-long bending beam actuator. As shown in FIG. 19, bending stiffness and deflection constraints cannot be simultaneously met at this length scale. When a bending beam is thin enough to offer sufficient deflections 1900 (e.g., a range 1901 of about 10 μm to 20 μm), the beam's stiffness 1902 is too low to resist the loads applied by the user during use. In contrast, as shown in FIG. 20, both constraints can be simultaneously met by a tactel at this length scale according to some embodiments. The performance of the tactel does not suffer significantly with increased thickness, and it is relatively easy to identify geometries that simultaneously meet both the stiffness 2000 and deflection 2001 (e.g., a range 2002 of about 10 μm to 20 μm) constraints. Similarly, the size scales of electroactive polymer actuators typically exceed the 1 mm² target, and more importantly, the actuation speeds of electroactive polymer actuators are below what is necessary for a rapidly-refreshable display that can display information in an intuitive, spatial/temporal fashion.

Amplifier angle θ can be optimized according to some embodiments. In operation of some embodiments, the top of each tactel moves up and down as its actuator lengthens and contracts horizontally. The ratio of the vertical deflection dy to the horizontal deflection dx is the amplification factor A, where A=dy/dx. For an embodiment with an amplifier comprised of rigid bars and ideal hinges, the amplification factor depends on the angle θ as A=cot(θ). For small values of angle θ (e.g., less than about 1.5 degrees), amplification factor A can exceed 40. This enables large vertical displacements (as could be obtained from a bending cantilever beam) in some embodiments, but without the low vertical stiffness characteristic of cantilever beam bending.

According to some embodiments, smaller values of the angle θ are advantageous for maximizing the amplification factor. However, larger values of the angle θ are advantageous from the point of view of the blocking force. When a vertical force is applied to the tactel by the user, it produces a horizontal force in the extension actuator, as shown in FIG. 18B. If this horizontal force is large enough, it can overpower the piezoelectric actuator and prevent the tactel from vibrating. Smaller values of the angle θ produce larger horizontal forces in the actuator. This presents a challenge because piezoelectric actuators are characterized by a blocking force, which is the force necessary to stop displacement (deflection or extension) of the actuator. The higher the actuator's displacement, the lower the blocking force that is required to prevent displacement. As the values of the angle θ get smaller, the axial force applied to the actuator gets larger, the required blocking force gets larger, and the maximum achievable displacement dx decreases. For an amplifier approximated as rigid bars connected by ideal hinges and a vertical force F applied by a user, the vertical component of the force at the actuator ends is F/2. The axial force in the rigid bars is F/(2 sin(θ)), and the axial force applied to the actuating beam is F·cot(θ)/2. If the value of the angle θ is too small, the actuator will not be able to overcome the user's applied force.

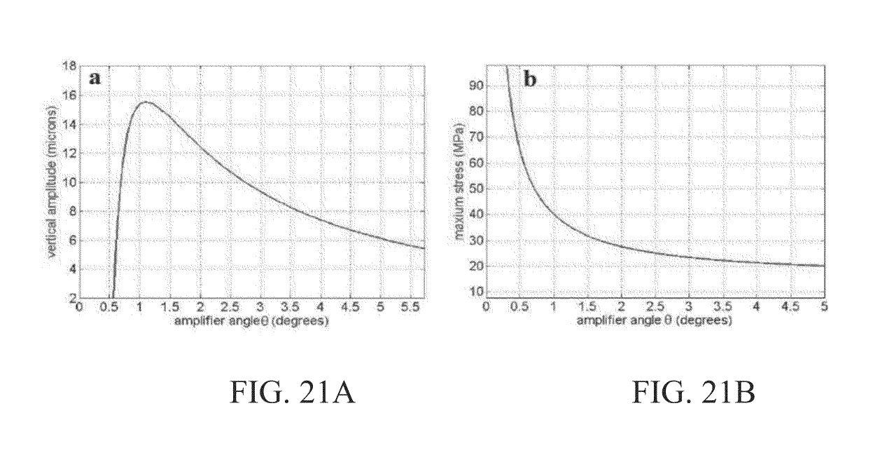

The tradeoff between actuator displacement and amplification factor results in an optimum angle θ below which the small value of displacement dx needed for blocking force to overcome the axial force overwhelms the large amplification factor A, and above which the small value of A overwhelms the large value of displacement dx. FIG. 21A is a plot of the deflection as a function of the angle θ for a PZT actuator that is 2.5-mm long, 400-μm wide, and 250-μm thick in accordance with some embodiments. The applied voltage alternated between 200 V in the poling direction and a lower −50 V opposite to the poling direction. The voltage values were selected to remain below the electric fields that would impact the actuator's polarization or electrical performance and are also below the limits on consumer electronic devices. In this calculation, the load applied by the user to each tactel was taken to be about 0.1 N, which is about five times larger than the minimum necessary force for tactile sensing. In addition, the force from a blunt fingertip will in practice be spread over a larger number of tactels according to some embodiments. This calculation therefore provides a conservative overestimate of the impact of blocking force constraints on tactel operation.

As shown in FIG. 21A, the maximum deflection for this conservative case was calculated to be greater than 15 μm for a starting angle of about 1.25 degrees, a substantial amplitude for a small tactel area of 1 mm². The actual angle can deviate from the optimal angle by about 0.5 degrees without substantial loss of vertical amplitude. Although x-poling (i.e., antiparallel poling in a bilayer actuator) would offer the same performance for half of the applied voltage, these results were calculated for a y-poled actuator. Because y-poled actuators only require contacts to the two sides of the actuator rather than also requiring one to the midplane of the actuator, embodiments with y-poled actuators can be more readily manufactured.

Some embodiments are further constrained by vertical stiffness, failure stress, and frequency. The vertical forces F/2 applied to the two ends of the extensional actuator will tend to bend it. If a user's finger tissue is stiffer than the actuator, actuation of the tactel can be suppressed, and sensitivity can be reduced. Based on the effective modulus of tissue (e.g., 200 kPa, which is equal to that of skin tissue and 100 times greater than that of fat tissue), the stiffness of each tactel should be designed to be at least 5×10⁴ N/m. In other words, with this stiffness, a conservatively large applied sensing load of 0.1 N/tactel will produce only 2 μm of vertical displacement in the tactel, almost an order of magnitude less than its vibrational amplitude.

In some embodiments, as the value of the angle θ decreases and the axial force in the actuator increases, the maximum stress in the actuator (e.g., bending stress from vertical forces plus uniform axial stress from horizontal forces) approaches the failure stress. FIG. 21B is a plot of the maximum total stress as a function of the angle θ for a PZT actuator that is 2.5-mm long, 400-μm wide, and 250-μm thick in accordance with some embodiments. For an angle of about 1.25 degrees at which optimal deflection is predicted, the maximum stress is 70% of the maximum stress for confident everyday use given by the manufacturer. Failure stress constraints therefore must be considered in some embodiments but do not need to be a dominant design constraint. Likewise, calculations showed that frequency constraints (e.g., a resonant frequency greater than 400 Hz) are easily met in most embodiments.

Based on the above criteria and analytical results, the following baseline architecture specifications are preferred for a 1 mm² tactel according to some embodiments. An array of actuators is monolithically manufactured from a single integral sheet. Although each tactel has one long dimension, it can be patterned as an offset array of more than one tactel. The offset array ensures that the tactel-to-tactel spacing is nearly uniform in the two in-plane directions. For example, perfectly uniform tactel-to-tactel spacing would result in the tactels being spaced approximately 1 mm on center. Each actuator has a length, width, and thickness of about 2.5 mm, about 400 μm, and about 250 μm respectively. Each actuator is center-mounted onto an underlying printed circuit board. The nominal angle of the amplifier mechanism is about 1.25 degrees, with a tolerance of ±0.5 degrees. With positive and negative driving voltages of 200 V and −50 V respectively, the nominal performance is predicted to be as follows: 0.34 microns of lateral deflection of the extension actuator; amplification factor of 46; 15.5 microns of actuation amplitude; individual tactel area of 1 mm²; maximum stress in the actuator beam of 40 MPa; maximum operating frequency of much greater than 400 Hz; and structural stiffness (vertical) of 9×10⁴ N/m. Embodiments with these specifications feature an exceptionally high refresh rate and enable the proposed new modes of tactile information acquisition. The small tactels enable a compact system, and the architecture enables excellent robustness and display stiffness as compared with human tissue. The deflection is greater than 10 times the detection limit for higher frequency vibrations and may be increased still further through slight increases in the actuator area (i.e., slightly lower display density).

### Manufacturing

Although an actuator and an amplifier can be assembled by hand to form a functioning tactel, assembly by scalable means (e.g., batch-manufacturable processes) is preferable for some embodiments (e.g., large tactile displays). According to some embodiments, elements of tactels may be manufactured using techniques of microelectromechanical systems (MEMS) manufacturing, microfabrication, bulk micromachining, micromachining of piezoelectric materials, or microsystems technologies, including but not limited to molding and plating, wet etching and dry etching, electro discharge machining, 3D printing, and other technologies capable of manufacturing small devices. Actuators, amplifiers, and other elements of tactels also may be manufactured using macroscale techniques such as injection molding.

According to some embodiments, a piezoelectric plate may be manufactured to define an array of one or more actuators using any of several different techniques, such as laser machining, ultrasonic machining, or cutting with a water jet cutter. Alternatively, one or more actuators can be cut from commercially-available PZT sheets using, for example, laser ablation, laser machining, or waterjet cutting. The width of the through-layer cuts will be on the order of 100 microns or a few hundred microns. For a 100-micron-wide cut, this places the aspect ratio of the cuts at about 2:1 for a 200-micron-thick PZT layer, which is readily accomplished using, for example, laser ablation tools.

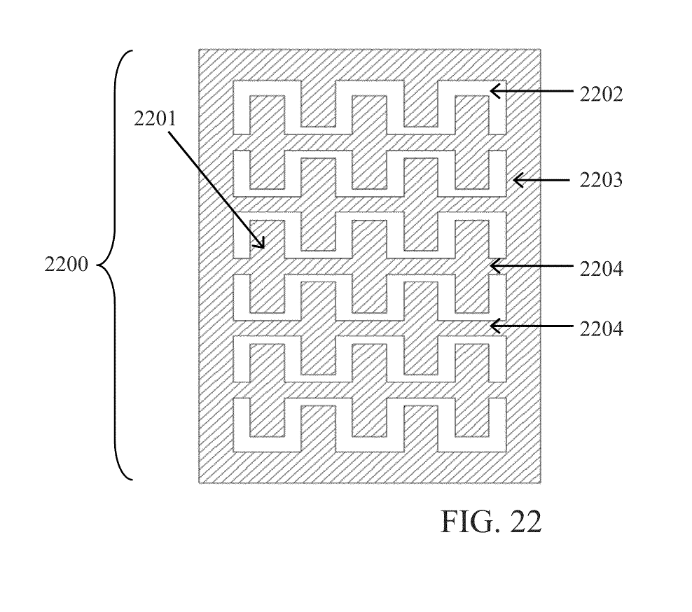

FIG. 22 is a schematic top view of a PZT sheet 2200 cut to form a predetermined interwoven pattern array of actuators 2201. Laser ablation of the PZT sheet 2200 leaves gaps 2202 around the actuators 2201 while maintaining a frame 2203 and center-mounted tethers 2204 between the individual actuators. In some embodiments, center-mounting leaves the ends of each actuator free to extend and contract to drive the actuation. Thus, in some embodiments, individual tactels are connected to adjacent tactels and to the frame that holds them all by tethers.

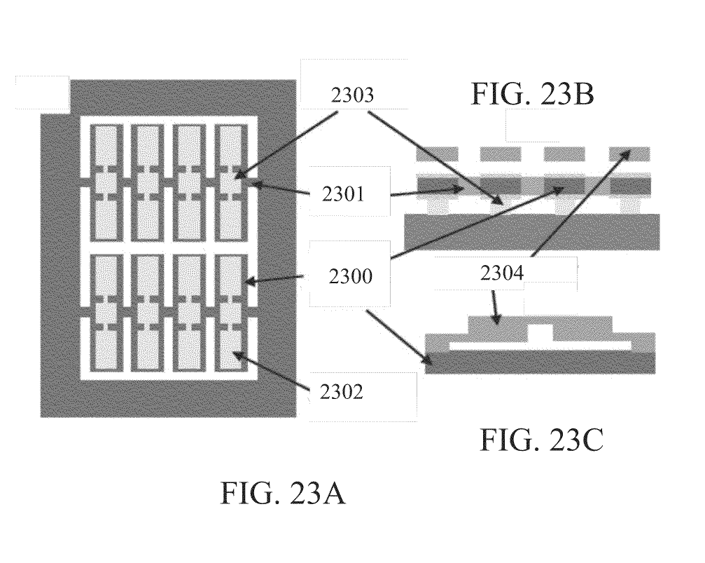

FIG. 23A is a schematic bottom view of a PZT plate with separate tactel connections according to some embodiments. An array of eight extension actuators 2300 can be laser-cut from a PZT plate, leaving the plate's frame and tethers 2301 between the actuators intact. In some embodiments, the electrodes that enable voltages to be applied to the tops and bottoms of each piezoelectric extensional actuator are also patterned to create the necessary functionality. For example, the electrode layer can be left intact on the upper side of the piezoelectric actuator array so that all of the upper surfaces are connected to a common ground. On the lower side of the array, nickel extension electrodes 2302 that control each tactel can be separated by laser etching as shown in FIG. 23A, by shallow waterjet cutting, or by using photolithography followed by an etch process.

For lab-scale display testing, the electrical and mechanical connections to each tactel (which are separated on average by about 1 mm) can be made using arrays of spring-loaded “pogo pin” connections to contact each lower electrode. The pogo-pins connect to an underlying printed circuit board (PCB) through which the control signals can be routed. For larger-scale implementation and long term use, the electrical and mechanical connections to each tactel can be made directly by making a low temperature solder connection from the center of the underside of each actuator beam to the underlying PCB or silicon chip. This ultimate PCB or chip can host the control circuitry, as well as provide both mechanical support and electrical contact to the tactels in the array. FIG. 23B is a schematic side view of a PZT plate assembled with solder connections 2303 onto PCB substrate.

To validate extensional actuator fabrication according to some embodiments, “short loop” tests can be used to confirm the correct functioning of the actuator fabrication process (including electrode patterning and definition of the individual tactels in their supporting frame) prior to its integration into the full display manufacturing process. The actuator fabrication processes can be demonstrated, and the resulting geometry can be measured using microscopes capable of quantitative dimensional measurement. The electrical properties (e.g., resistance and capacitance) of the fabricated array can be measured and compared with expected values to confirm that the piezoelectric material has not been damaged during processing.

The process described so far creates monolithic arrays of extensional actuators according to some embodiments. To complete a tactile display according to further embodiments, the process also needs to create amplifiers on top of the actuators, preferably in an efficient and integrated manner. FIG. 23C illustrates an amplifier geometry that provides the necessary amplifier functionality according to some embodiments while also being consistent with batch manufacturable processes, such as 3D printing, screen printing, injection molding, and stamping from a metal sheet. Amplifiers may be manufactured in place on a surface of an actuator or manufactured separately and then integrated onto the surface of an actuator. In FIG. 23C, an amplifier member 2304 is mounted on a piezoelectric extensional actuator 2300. Similarly, protrusions or pins may be manufactured in place on a surface of an amplifier or manufactured separately and then integrated onto the surface of an amplifier.

According to some embodiments, the thicker parts of the amplifier in FIG. 23C represent the two, nominally rigid bars of the scissor mechanism, as well as the anchors where the structure connects to the substrate. The thinner parts of the amplifier mechanism (e.g., thinner in the width direction and/or thickness direction) represent the flexural bending hinges (i.e., living hinges). Since flexural rigidity is proportional to thickness cubed, a modest reduction in thickness (e.g., by a factor of 3) can greatly reduce the stiffness of the hinges as compared with the nominally rigid elements (e.g., by a factor of 27). This reduction in thickness can effectively localize the bending to the correct regions. In some embodiments, to provide an appropriate starting angle θ, the flexural hinges that connect the rigid bars at the center can be located nearer the tops of the rigid bars, whereas the flexural hinges that connect the rigid bars to the substrate can be located nearer the bottom of the rigid bars. For example, for a 2.5-mm-long actuator, the optimal amplifier angle θ corresponds to a difference in height between the flexural hinges that connect the rigid arms to the actuator and the flexural hinge that connects the rigid arms to each other of approximately 50 μm. The amplifier geometry then approximates the desired structure of two angled, nominally rigid bars, each connected by bending elements in accordance with some embodiments.

The details of the hinge geometry can be varied in some embodiments to ensure that an optimally robust, effective geometry is chosen. Small hinge deformations (e.g., on the order of 0.25 degrees) will minimize plastic deformation.

In accordance with some embodiments, the amplifiers can be formed as a monolithic array connected together by a set of snap-off tabs or tabs that may be removed by machining. In further embodiments, after an amplifier array is written, the amplifiers can be adhered to the patterned piezoelectric extensional actuator plate and released via the snap-off tabs or machinable tabs.

Three-dimensional printing can provide rapid fabrication with an excellent degree of control over the final amplifier geometry in accordance with some embodiments. For example, 3D printing can provide separate control of the thickness of the rigid bars of an amplifier and the vertical placement of the hinges (i.e., the hinge angle). Amplifier arrays can be fabricated from a typical structural material for stereo lithography (e.g., a cured rosin such as Accura® 40 plastic, available from 3D Systems Corp. (Rock Hill, S.C.)); however, there is increasing variety in the materials that are available to be 3D-printed (e.g., photo-solidified polymer and conductive polymer).

Alternatively, the structural and sacrificial layers necessary to form the amplifiers can be screen-printed instead of 3D-printed according to some embodiments. Screen printing with structural and sacrificial layers is an increasingly common method of producing mechanical elements at moderate MEMS size scales. Structural and sacrificial materials can be selected for a combination of device performance and effectiveness in the screen printing process. In some embodiments, screen printing can be used to produce (a) an electrically insulating layer atop an actuator, (b) appropriate sacrificial layers under amplifier elements, (c) thick structural layers to form the rigid bars of an amplifier, (d) living hinges, and/or (e) protrusions near the peak of an amplifier that protrude through the upper protective plate for tactile sensing by a user. These structures can be screen printed before the full definition of the actuator array (i.e., onto a more straightforward flat surface) or after the definition of the actuator array (i.e., onto a non-planar surface). The former eases the amplifier patterning at the expense of the actuator patterning; the latter eases the actuator patterning at the expense of the amplifier patterning.

Alternatively, injection molding can provide rapid fabrication of individual amplifiers or of arrays of multiple amplifiers. The molds from which the injection-molded parts are made may be manufactured by conventional machining or by three dimensional printing.

Other fabrication alternatives include but are not limited to stamping. In some embodiments, an amplifier structure can be integrated with the actuator layer by stamping an interconnected plate of scissor structures with flexural hinges out of a single sheet of relatively rigid polymer or metal and affixing it en masse onto the actuator plate.

In some embodiments, a cover (e.g., a cap plate or top plate) can be perforated with access holes through which protrusions or pins on the tops of the individual tactels protrude. The cover can be designed for adequate bending rigidity and passive mechanical alignment over the tactel array. In further embodiments, a surface protective layer (e.g., a low-stiffness polymer film) can be included to protect the device from moisture and dust in the environment. This layer is analogous to the aftermarket polymer films used to protect a smartphone screen from scratches without hampering the interaction between the fingers and the active display.

### Tactile Display Systems

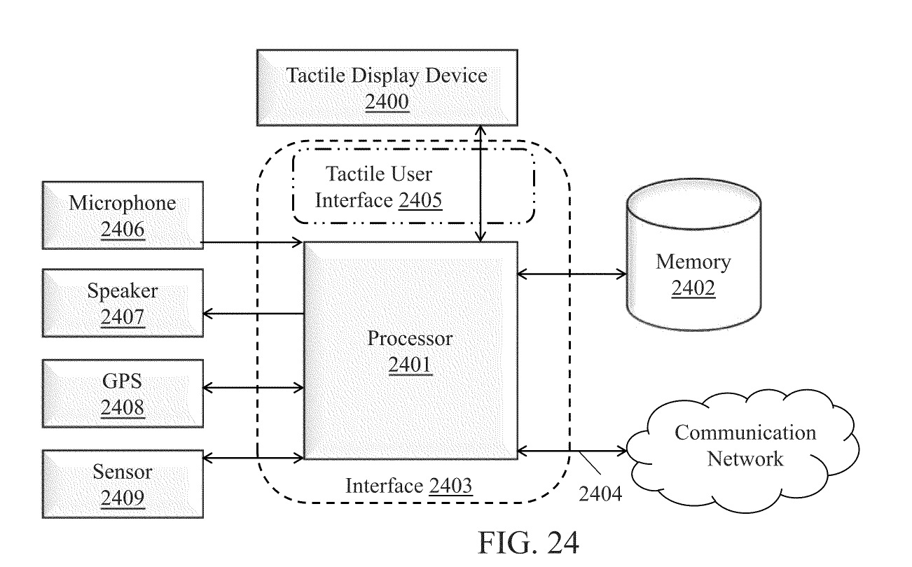

Referring to FIG. 24, in a typical operating environment, a system for communicating information through a tactile display can include, but is not limited to, a tactile display device 2400, processor 2401, memory 2402, interface 2403, network connection 2404, tactile user interface 2405 (each described in detail below) in accordance with some embodiments. In practice, embodiments can be implemented in various forms of hardware, software, firmware, or a combination thereof. In some embodiments, modules are implemented in software as application programs that are then executed by user equipment. The user equipment can include a tactile display device as well as desktop computers, laptop computers, netbooks, smartphones, navigation devices, and other forms of audio/visual equipment that can communicate with a network and/or tactile display device.

According to some embodiments, a system for communicating information through a tactile display includes one or more processors, shown collectively as processor 2401 in FIG. 24, that execute instructions and run software that may be stored in memory 2402. In some embodiments, the software needed for implementing a process or a database includes a high level procedural or an object-orientated language such as C, C++, C#, Java, Perl, or MATLAB®. The software may also be implemented in assembly language if desired. Processor 2401 can be any applicable processing unit that combines a CPU, an application processing unit, and memory. Applicable processors can include any microprocessor (single or multiple core), system on chip (SoC), microcontroller, digital signal processor (DSP), graphics processing unit (GPU), combined hardware and software logic, or any other integrated circuit capable of processing instructions. Suitable operating systems can include MAC OS, Linux, Unix, MS-DOS, Windows, or any other operating system capable of executing the processes described herein.

Some embodiments may include one or more suitable memory devices, shown collectively as memory 2402 in FIG. 24, such as a non-transitory computer readable medium, flash memory, a magnetic disk drive, an optical drive, a programmable read-only memory, and/or a read-only memory. Memory 2402 stores the instructions for applications (e.g., selective actuation of tactels in the tactile display device 2400 to produce pre-associated with information), which are executed by processor 2401. Memory 2402 also may store data relating to patterns, including spatial patterns, spatiotemporal patterns, sensations of motion, and changes in frequency.

According to some embodiments, a system for communicating information through a tactile display includes one or more interfaces, shown collectively as interface 2403 in FIG. 24, that allow the processor 2401 to interact with software, hardware, or peripheral elements, including but not limited to the tactile display device 2400, memory 2402, and network connection 2404 (using, e.g., a modem, wireless transceiver, or wired network connection). In some embodiments, interface 2403 provides input and/or output mechanisms to communicate with a user. For example, as an input and/or output mechanism, interface 2403 can operate to receive information from as well as transmit instructions to the tactile display device 2400. Other suitable input/output devices to use with interface 2403 may include, but are not limited to, a microphone 2406, a speaker 2407, a navigation device (e.g., a compass and/or a device that receives Global Positioning System (GPS) signals) 2408, a sensor (e.g., a position sensor, a proximity sensor, a motion detector, a light sensor, and/or an image sensor) 2409, a modem, a transceiver, a touch screen, a keyboard, a pen device, a trackball, a touch pad, and a mouse.

Some embodiments may include special tactile user interface 2405 to allow users to interact with the system using tactile patterns and indicators. For example, a user may use input/output devices to communicate with the system and manipulate tactels and tactel-associated data over tactile user interface 2405. Interface 2403 and tactile user interface 2405 can operate under a number of different protocols. Interface 2403 and tactile user interface 2405 also can be implemented in software or hardware to send and receive signals in a variety of mediums, such as optical, copper, and wireless, and in a number of different protocols some of which may be non-transient.

The subject matter described herein can be implemented in digital electronic circuitry, or in computer software, firmware, or hardware, including the structural means disclosed in this specification and structural equivalents thereof, or in combinations of them. The subject matter described herein can be implemented as one or more computer program products, such as one or more computer programs tangibly embodied in an information carrier (e.g., in a machine readable storage device), or embodied in a propagated signal, for execution by, or to control the operation of, data processing apparatus (e.g., a programmable processor, a computer, or multiple computers). A computer program (also known as a program, software, software application, or code) can be written in any form of programming language, including compiled or interpreted languages, and it can be deployed in any form, including as a stand-alone program or as a module, component, subroutine, or other unit suitable for use in a computing environment. A computer program does not necessarily correspond to a file. A program can be stored in a portion of a file that holds other programs or data, in a single file dedicated to the program in question, or in multiple coordinated files (e.g., files that store one or more modules, sub programs, or portions of code). A computer program can be deployed to be executed on one computer or on multiple computers at one site or distributed across multiple sites and interconnected by a communication network.

The processes and logic flows described in this specification, including the method steps of the subject matter described herein, can be performed by one or more programmable processors executing one or more computer programs to perform functions of the subject matter described herein by operating on input data and generating output. The processes and logic flows can also be performed by, and apparatus of the subject matter described herein can be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processor of any kind of digital computer. Generally, a processor will receive instructions and data from a read only memory or a random access memory or both. The essential elements of a computer are a processor for executing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. Information carriers suitable for embodying computer program instructions and data include all forms of nonvolatile memory, including by way of example semiconductor memory devices, (e.g., EPROM, EEPROM, and flash memory devices); magnetic disks, (e.g., internal hard disks or removable disks); magneto optical disks; and optical disks (e.g., CD and DVD disks). The processor and the memory can be supplemented by, or incorporated in, special purpose logic circuitry.

To provide for interaction with a user, the subject matter described herein can be implemented on a computer having a display device, e.g., a CRT (cathode ray tube) or LCD (liquid crystal display) monitor, for displaying information to the user and a keyboard and a pointing device, (e.g., a mouse or a trackball), by which the user can provide input to the computer. Other kinds of devices can be used to provide for interaction with a user as well. For example, feedback provided to the user can be any form of sensory feedback, (e.g., visual feedback, auditory feedback, or tactile feedback), and input from the user can be received in any form, including acoustic, speech, or tactile input.

The subject matter described herein can be implemented in a computing system that includes a back end component (e.g., a data server), a middleware component (e.g., an application server), or a front end component (e.g., a client computer having a graphical user interface or a web browser through which a user can interact with an implementation of the subject matter described herein), or any combination of such back end, middleware, and front end components. The components of the system can be interconnected by any form or medium of digital data communication, e.g., a communication network. Examples of communication networks include a local area network (“LAN”) and a wide area network (“WAN”), e.g., the Internet.

It is to be understood that the disclosed subject matter is not limited in its application to the details of construction and to the arrangements of the components set forth in the following description or illustrated in the drawings. The disclosed subject matter is capable of other embodiments and of being practiced and carried out in various ways. Also, it is to be understood that the phraseology and terminology employed herein are for the purpose of description and should not be regarded as limiting.

As such, those skilled in the art will appreciate that the conception, upon which this disclosure is based, may readily be utilized as a basis for the designing of other structures, methods, and systems for carrying out the several purposes of the disclosed subject matter. It is important, therefore, that the claims be regarded as including such equivalent constructions insofar as they do not depart from the spirit and scope of the disclosed subject matter.

Although the disclosed subject matter has been described and illustrated in the foregoing exemplary embodiments, it is understood that the present disclosure has been made only by way of example, and that numerous changes in the details of implementation of the disclosed subject matter may be made without departing from the spirit and scope of the disclosed subject matter, which is limited only by the claims which follow.

1. A high-resolution actuating array, comprising:
an array of two or more actuators in a plane, each having a long dimension in a first direction in the plane;
one or more electrodes positioned in contact with one or more surfaces of each actuator, the two or more actuators in the array being independently configured and arranged to at least one of contract and expand in the first direction upon application of one or more electric voltages to the one or more electrodes; and
an amplifier with one or more bendable elements and one or more rigid arms positioned in contact with each actuator, wherein at least one rigid arm is flexibly attached to a surface of the actuator, the at least one rigid arm being configured and arranged to rotate away from the surface of the actuator when the actuator contracts in the first direction and to rotate toward the surface of the actuator when the actuator expands in the first direction.

2. The high-resolution actuating array of claim 1, wherein the two or more actuators in the array are configured to have operating frequencies of approximately 10 Hz to 400 Hz.

3. The high-resolution actuating array of claim 1, wherein the two or more actuators in the array are configured and arranged to be independently actuated with at least one of a unique memory element in an underlying memory circuit, a unique voltage signal, and a unique current flow path.

4. The high-resolution actuating array of claim 1, further comprising at least one of a printed circuit board baseplate and a silicon chip configured and arranged for mounting the array of actuators.

5. The high-resolution actuating array of claim 1, wherein at least one of the one or more bendable elements is at least one of a pin hinge, a magnetic hinge, and a living hinge.

6. The high-resolution actuating array of claim 1, wherein each amplifier comprises:
a pair of rigid arms, each having a first end connected with a first bendable element to an opposite end of the actuator along its long dimension; and
a second bendable element connected to each second end of the pair of rigid arms,
wherein the pair of rigid arms are configured and arranged to rotate away from the surface of the actuator to form an inverted V-shape when the actuator contracts in the first direction and rotate toward the surface of the actuator when the actuator expands in the first direction.

7. The high-resolution actuating array of claim 1, wherein each amplifier comprises:
one or more rigid arms, each having a first end connected with a first bendable element to an end of the actuator along its long dimension; and
a rigid wall protruding from the surface of the actuator, wherein a second end of each of the one or more rigid arms is in contact with a surface of the wall,
wherein each second end of the one or more rigid arms is configured and arranged to move away from the surface of the actuator in a second direction, the second direction being approximately perpendicular to the plane, when the actuator contracts in the first direction and to move toward the surface of the actuator in the second direction when the actuator expands in the first direction.

8. The high-resolution actuating array of claim 1, wherein each amplifier comprises:
a first pair of rigid arms, each having a first end connected with a first bendable element to an opposite end of the actuator along its long dimension; and
a second bendable element connected to each center of the first pair of rigid arms,
wherein the first pair of rigid arms is configured and arranged to rotate away from the surface of the actuator to form an X-shape when the actuator contracts in the first direction and to rotate toward the surface of the actuator in the second direction when the actuator expands in the first direction.

9. The high-resolution actuating array of claim 8, wherein each amplifier further comprises:
a second pair of rigid arms, each having a first end connected with a third bendable element to a second end of an opposite arm of the first pair of rigid arms; and
a final bendable element connected to each second end of the second pair of rigid arms,
wherein the second pair of rigid arms is configured and arranged to rotate away from the surface of the actuator to form an inverted V-shape when the actuator contracts in the first direction and to rotate toward the surface of the actuator when the actuator expands in the first direction.

10. The high-resolution actuating array of claim 8, wherein each amplifier further comprises:
N pairs of rigid arms, wherein N is a whole number; and
N bendable elements, each connected to each center of a pair of rigid arms,
wherein the N pairs of rigid arms are stacked such that each arm has a first end connected with another bendable element to an opposite second end of an arm of a previous pair of rigid arms in the stack,
wherein the N pairs of rigid arms are configured and arranged to rotate away from the surface of the actuator to form N X-shapes when the actuator contracts in the first direction and to rotate toward the surface of the actuator when the actuator expands in the first direction.

11. The high-resolution actuating array of claim 10, wherein each amplifier further comprises:
a final pair of rigid arms, each having a first end connected with another bendable element to a second end of an opposite arm of the Nth pair of rigid arms; and
a final bendable element connected to each second end of the final pair of rigid arms,
wherein the final pair of rigid arms is configured and arranged to rotate away from the surface of the actuator to form an inverted V-shape when the actuator contracts in the first direction and to rotate toward the surface of the actuator when the actuator expands in the first direction.

12. The high-resolution actuating array of claim 1, further comprising a pin protruding from each amplifier in a second direction, the second direction being approximately perpendicular to the plane.

13. The high-resolution actuating array of claim 1, further comprising at least one of a cover and cap plate defining an array of two or more access holes configured to align with an array of two or more pins.

14. The high-resolution actuating array of claim 1, further comprising a pin protruding from each amplifier in the first direction.

15. The high-resolution actuating array of claim 1, further comprising at least one of a cover and cap plate defining an array of two or more access holes configured to align with an array of two or more pins.

16. The high-resolution actuating array of claim 1, wherein the array of two or more actuators has a rectilinear layout.

17. The high-resolution actuating array of claim 1, wherein the array of two or more actuators has an offset layout.

18. The high-resolution actuating array of claim 1, wherein the array of two or more actuators in the plane is stacked with a second array in a parallel plane, the second array comprising:
two or more actuators, each having a long dimension in the first direction;
one or more electrodes positioned in contact with one or more surfaces of each actuator, the two or more actuators in the second array being independently configured and arranged to at least one of contract and expand in the first direction upon application of one or more electric voltages to the one or more electrodes; and
an amplifier with one or more bendable elements and one or more rigid arms positioned in contact with each actuator, wherein at least one rigid arm is flexibly attached to a surface of the actuator, the at least one rigid arm being configured and arranged to rotate away from the surface of the actuator when the actuator contracts in the first direction and to rotate toward the surface of the actuator when the actuator expands in the first direction.

19. The high-resolution actuating array of claim 18, further comprising N arrays of two or more actuators stacked in N parallel planes, wherein N is a whole number.

20. A method of using a high-resolution actuating array, comprising:
obtaining an array of two or more actuators in a plane, each having a long dimension in a first direction in the plane, wherein an amplifier with one or more bendable elements and one or more rigid arms is positioned in contact with each actuator and wherein at least one rigid arm is flexibly attached to a surface of the actuator; and
applying one or more electric voltages to one or more electrodes positioned in contact with one or more surfaces of at least one actuator such that the at least one actuator at least one of contracts and expands in the first direction and the at least one rigid arm rotates away from the surface of the actuator when the actuator contracts in the first direction and rotates toward the surface of the actuator when the actuator expands in the first direction.

21. The method of using a high-resolution actuating array of claim 20, wherein the two or more actuators in the array are configured to have operating frequencies of approximately 10 Hz to 400 Hz.

22. The method of using a high-resolution actuating array of claim 20, wherein the two or more actuators in the array are configured and arranged to be independently actuated with at least one of a unique memory element in an underlying memory circuit, a unique voltage signal, and a unique current flow path.

23. The method of using a high-resolution actuating array of claim 20, wherein at least one of the one or more bendable elements is at least one of a pin hinge, a magnetic hinge, and a living hinge.

24. The method of using a high-resolution actuating array of claim 20, wherein each amplifier comprises:
a pair of rigid arms, each having a first end connected with a first bendable element to an opposite end of the actuator along its long dimension; and
a second bendable element connected to each second end of the pair of rigid arms,
wherein the pair of rigid arms are configured and arranged to rotate away from the surface of the actuator to form an inverted V-shape when the actuator contracts in the first direction and rotate toward the surface of the actuator when the actuator expands in the first direction.

25. The method of using a high-resolution actuating array of claim 20, wherein each amplifier comprises:
one or more rigid arms, each having a first end connected with a first bendable element to an end of the actuator along its long dimension; and
a rigid wall protruding from the surface of the actuator, wherein a second end of each of the one or more rigid arms is in contact with a surface of the wall,
wherein each second end of the one or more rigid arms is configured and arranged to move away from the surface of the actuator in a second direction, the second direction being approximately perpendicular to the plane, when the actuator contracts in the first direction and to move toward the surface of the actuator in the second direction when the actuator expands in the first direction.

26. The method of using a high-resolution actuating array of claim 20, wherein each amplifier comprises:
a first pair of rigid arms, each having a first end connected with a first bendable element to an opposite end of the actuator along its long dimension; and
a second bendable element connected to each center of the first pair of rigid arms,
wherein the first pair of rigid arms is configured and arranged to rotate away from the surface of the actuator to form an X-shape when the actuator contracts in the first direction and to rotate toward the surface of the actuator in the second direction when the actuator expands in the first direction.

27. The method of using a high-resolution actuating array of claim 26, wherein each amplifier further comprises:
a second pair of rigid arms, each having a first end connected with a third bendable element to a second end of an opposite arm of the first pair of rigid arms; and
a final bendable element connected to each second end of the second pair of rigid arms,
wherein the second pair of rigid arms is configured and arranged to rotate away from the surface of the actuator to form an inverted V-shape when the actuator contracts in the first direction and to rotate toward the surface of the actuator when the actuator expands in the first direction.

28. The method of using a high-resolution actuating array of claim 27, wherein each amplifier further comprises:
N pairs of rigid arms, wherein N is a whole number; and
N bendable elements, each connected to each center of a pair of rigid arms,
wherein the N pairs of rigid arms are stacked such that each arm has a first end connected with another bendable element to an opposite second end of an arm of a previous pair of rigid arms in the stack,
wherein the N pairs of rigid arms are configured and arranged to rotate away from the surface of the actuator to form N X-shapes when the actuator contracts in the first direction and to rotate toward the surface of the actuator when the actuator expands in the first direction.

29. The method of using a high-resolution actuating array of claim 27, wherein each amplifier further comprises:
a final pair of rigid arms, each having a first end connected with another bendable element to a second end of an opposite arm of the Nth pair of rigid arms; and
a final bendable element connected to each second end of the final pair of rigid arms,
wherein the final pair of rigid arms is configured and arranged to rotate away from the surface of the actuator to form an inverted V-shape when the actuator contracts in the first direction and to rotate toward the surface of the actuator when the actuator expands in the first direction.

30. The method of using a high-resolution actuating array of claim 20, wherein the array of two or more actuators has a rectilinear layout.

31. The method of using a high-resolution actuating array of claim 20, wherein the array of two or more actuators has an offset layout.

32. The method of using a high-resolution actuating array of claim 20, wherein the array of two or more actuators in the plane is stacked with a second array in a parallel plane comprising:
two or more actuators, each having a long dimension in the first direction;
one or more electrodes positioned in contact with one or more surfaces of each actuator, the two or more actuators in the second array being independently configured and arranged to at least one of contract and expand in the first direction upon application of one or more electric voltages to the one or more electrodes; and
an amplifier with one or more bendable elements and one or more rigid arms positioned in contact with each actuator, wherein at least one rigid arm is flexibly attached to a surface of the actuator, the at least one rigid arm being configured and arranged to rotate away from the surface of the actuator when the actuator contracts in the first direction and to rotate toward the surface of the actuator when the actuator expands in the first direction.

33. The method of using a high-resolution actuating array of claim 20, further comprising N arrays of two or more actuators stacked in N parallel planes, wherein N is a whole number.

34. A method of manufacturing a high-resolution actuating array, comprising:
cutting an array of two or more actuators in a plane from a piezoelectric sheet, each actuator having a long dimension in a first direction in the plane;
defining one or more electrodes positioned in contact with one or more surfaces of each actuator, the two or more actuators in the array being independently configured and arranged to at least one of contract and expand in the first direction upon application of one or more electric voltages to the one or more electrodes; and
fabricating an amplifier with one or more bendable elements and one or more rigid arms is positioned in contact with each actuator, wherein at least one rigid arm is flexibly attached to a surface of the actuator, the at least one rigid arm being configured and arranged to rotate away from the surface of the actuator when the actuator contracts in the first direction and to rotate toward the surface of the actuator when the actuator expands in the first direction.

35. The method of manufacturing a high-resolution actuating array of claim 34, wherein the array of two or more actuators is cut using at least one of laser cutting, ultrasonic machining, and waterj et cutting.

36. The method of manufacturing a high-resolution actuating array of claim 35, wherein gaps are cut into the piezoelectric sheet to maintain at least one of a frame around the array and one or more tethers between the two or more actuators.

37. The method of manufacturing a high-resolution actuating array of claim 34, wherein the array of two or more actuators is patterned with a rectilinear layout.

38. The method of manufacturing a high-resolution actuating array of claim 34, wherein the array of two or more actuators is patterned with an offset layout.

39. The method of manufacturing a high-resolution actuating array of claim 34, wherein the one or more electrodes are defined on the one or more surfaces of at least one actuator by at least one of laser machining, ultrasonic machining, and waterjet cutting, photolithography, and other forms of etching.

40. The method of manufacturing a high-resolution actuating array of claim 34, wherein the amplifier is fabricated using at least one of 3D printing, screen printing, injection molding, and stamping from a metal sheet.

41. The method of manufacturing a high-resolution actuating array of claim 40, wherein the amplifier is formed as a monolithic array connected together by at least one of a set of snap-off tabs and tabs that can be removed by machining.

42. A high-resolution tactile display system, comprising:
a high-resolution actuating array according to claim 1;
a processor configured to encode information as one or more tactons and signal the application of one or more electric voltages to the one or more electrodes of at least one actuator; and
storage for storing data and executable instructions to be used by the processor.

43. The high-resolution tactile display system of claim 42, wherein the one or more tactons include at least one of a spatial pattern of actuation, a spatiotemporal pattern of actuation, a series of actuations sensed as motion, a series of rhythmic actuations, a variation in amplitude, and a variation in operating frequency.

44. The high-resolution tactile display system of claim 42, further comprising a tactile user interface.

45. The high-resolution tactile display system of claim 42, further comprising at least one of a microphone, a speaker, a navigation device, a sensor, and a network connection.

46. A method of using a high-resolution tactile display system, comprising:
obtaining information for display;
encoding the information as one or more tactons; and
signaling the application of one or more electric voltages to one or more electrodes of at least one actuator in a high-resolution actuating array according to claim 1.

47. The method of using a high-resolution tactile display system of claim 46, wherein the one or more tactons include at least one of a spatial pattern of actuation, a spatiotemporal pattern of actuation, a series of actuations sensed as motion, a series of rhythmic actuations, a variation in amplitude, and a variation in operating frequency.
